(19) United States
(12) Patent Application Publication
(10) Pub. No.: US 2023/0232691 A1
(43) Pub. Date: Jul. 20, 2023

(54) DISPLAY DEVICE

(71) Applicant: Samsung Display Co., Ltd., Yongin-Si (KR)

(72) Inventors: HWA YEUL OH, Hwaseong-si (KR); Song Ee LEE, Seoul (KR); Jeong Ki KIM, Hwaseong-si (KR)

(21) Appl. No.: 17/945,527

(22) Filed: Sep. 15, 2022

(30) Foreign Application Priority Data
Jan. 19, 2022 (KR) 10-2022-0007644

(51) Int. Cl. H01L 27/32; H01L 51/52

(52) U.S. Cl. CPC H01L 27/322; H01L 51/5268; H01L 27/3244

(57) ABSTRACT

A display device is provided. The display device includes a first substrate; a second substrate facing the first substrate; light-emitting elements disposed between the first and second substrates, the light-emitting elements forming first light-emitting areas; first light-transmitting members disposed between the second substrate and the light-emitting elements; and color filter members disposed between the second substrate and the first light-transmitting members, wherein the color filter members form first filtering pattern areas that selectively transmit light and overlap with the first light-emitting areas, wherein the first light-transmitting members overlap with the first light-emitting areas and the first filtering pattern areas and comprise light scatterers that scatter light, and a width of the first light-transmitting members is greater than a width of the first light-emitting areas and a width of the first filtering pattern areas.

### CROSS-REFERENCE TO RELATED APPLICATION

This application claims priority from Korean Patent Application No. 10-2022-0007644 filed on Jan. 19, 2022 in the Korean Intellectual Property Office, and all the benefits accruing therefrom under 35 U.S.C. 119, the contents of which in their entirety are herein incorporated by reference.

### BACKGROUND

### 1. Field

The disclosure relates to a display device.

### 2. Description of the Related Art

Display devices have increasingly become important with the development of multimedia, and various types of display devices, such as a liquid crystal display (LCD) device, an organic light-emitting diode (OLED) display device, or the like, are widely used.

A self-luminous display device, which is a type of display device, includes light emitting elements such as OLEDs. Each of the light-emitting elements may include two electrodes facing each other and an emission layer interposed between the two electrodes. In a case where the light-emitting elements are OLEDs, electrons and holes from the two electrodes may recombine together in the emission layer to generate excitons, and light may be emitted in response to the transition of the excitons from an excited state to a ground state.

The self-luminous display device does not need a light source such as a backlight unit and can thus be implemented as a low-power consumption, thin, light-weight display device with high-quality characteristics such as wide viewing angles, high luminance and contrast, and a fast response speed, drawing attention as a next-generation display device.

### SUMMARY

Aspects of the disclosure provide a display device capable of preventing any smudges in a display area from becoming visible.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device comprises, a first substrate; a second substrate facing the first substrate; light-emitting elements disposed between the first and second substrates, the light-emitting elements forming first light-emitting areas; first light-transmitting members disposed between the second substrate and the light-emitting elements; and color filter members disposed between the second substrate and the first light-transmitting members, wherein the color filter members form first filtering pattern areas that selectively transmit light and overlap with the first light-emitting areas, wherein the first light-transmitting members overlap with the first light-emitting areas and the first filtering pattern areas and comprise light scatterers, which scatter light, and a width of the first light-transmitting members is greater than a width of the first light-emitting areas and a width of the first filtering pattern areas.

Second light-transmitting members may be disposed between the second substrate and the light-emitting elements and spaced apart from the first light-transmitting members, wherein the light-emitting elements form second light-emitting areas that are spaced apart from the first light-emitting areas, wherein the color filter members form second filtering pattern areas that are spaced apart from the first filtering pattern areas and overlap with the second light-emitting areas, wherein the second light-transmitting members may overlap with the second light-emitting areas and the second filtering pattern areas and comprise light scatterers, wherein a width of the second light-transmitting members may be greater than a width of the second light-emitting areas and a width of the second filtering pattern areas, and the width of the first light-transmitting members may be greater than the width of the second light-transmitting members.

The width of the first light-emitting areas may be substantially the same as the width of the second light-emitting areas, and the width of the first filtering pattern areas is substantially the same as the width of the second filtering pattern areas.

The color filter members may further comprise light-blocking areas that are disposed between the first filtering pattern areas and the second filtering pattern areas and block light; the first light-emitting areas and the second light-emitting areas may not overlap with the light-blocking areas; and the first light-transmitting members and the second light-transmitting members may overlap with the light-blocking areas.

A height of the first light-transmitting members may be less than a height of the second light-transmitting members.

A concentration of the light scatterers in the first light-transmitting members may be higher than a concentration of the light scatterers in the second light-transmitting members.

The first light-emitting areas may emit first light, the first light, may sequentially pass through the first light-transmitting members and the first filtering pattern areas, the second light-emitting areas may emit second light, the second light may sequentially pass through the second light-transmitting members and the second filtering pattern areas, and a luminance of the first light sequentially passing through the first light-transmitting members and the first filtering pattern areas may be substantially the same as an luminance of the second light sequentially passing through the second light-transmitting members and the second filtering pattern areas.

Each of the first light and the second light may have a wavelength of 380 nm to 500 nm and a peak wavelength of 440 nm to 480 nm.

The first light-transmitting members may further light scatterers embedded in base resin, the light scatterers may comprise a metal oxide, and the base resins may comprise one of an epoxy resin, an acrylic resin, and an imide resin.

The first light-transmitting members may further comprise wave shifters embedded in the base resins, and the wavelength shifters may comprise a semiconductor nanocrystal material for shifting the wavelength of light emitted from the first light-emitting areas.

According to another aspect of the disclosure, a display device comprises a light-emitting part emitting light; and a light-transmitting part disposed on the light-emitting part, the light-transmitting part having a first area and a second area that is adjacent to a first side of the first area, wherein the light-transmitting part comprises color filter members that selectively transmit light and a plurality of light-transmitting members disposed between the light-emitting part and the color filter members, wherein the light-transmitting members comprise light scatterers, and a width of the light-transmitting members increases along a first direction, in the first area of the light-transmitting part.

A height of the light-transmitting members may increase along the first direction, in the first area of the light-transmitting part.

A concentration of the light scatterers in the light-transmitting members may decrease along the first direction.

The width of the light-transmitting members may be substantially uniform in the second area of the light-transmitting part.

The height of the light-transmitting members and the concentration of the light scatterers in the light-transmitting members may be substantially constant in the second area of the light-transmitting part.

The light-emitting part may emit first light having a wavelength of 80 nm to 500 nm and a peak wavelength of 440 nm to 480 nm, the first light may pass through the light-transmitting part, and a luminance of the first light passing through the first area of the light-transmitting part may be substantially the same as a luminance of the second light passing through the second area of the light-transmitting part.

The light-emitting part may include a pixel-defining film that defines light-emitting areas emitting light, the light-transmitting part may further include a plurality of bank members that surround the light-transmitting members, the color filter members of the light-transmitting part may include a light-blocking areas that define filtering pattern areas selectively transmitting light therethrough, the bank members may not overlap with the light-emitting areas and the filtering pattern areas, and the pixel-defining film may not overlap with the light-blocking areas.

In the first area of the light-transmitting part, a width of the bank members may decreases in a direction toward the second area.

In the second area of the light-transmitting part, the width of the bank members may be substantially uniform.

The width of the light-transmitting members may vary along a second direction that intersects the first direction, in the first area of the light-transmitting part.

According to the aforementioned and other aspects of the disclosure, a display device capable of preventing any smudges in a display area from becoming visible can be provided.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view of a display device according to an embodiment of the disclosure;

FIG. 2 is a cross-sectional view of the display device of FIG. 1;

FIG. 3 is a plan view of the display device of FIG. 1;

FIG. 4 is an enlarged plan view of part Q1 of FIG. 3, particularly, a light-emitting part of the display device of FIG. 1;

FIG. 5 is an enlarged plan view of part Q1 of FIG. 3, particularly, a light-transmitting part of the display device of FIG. 1;

FIG. 6 is a cross-sectional view taken along line X1-X1′ of FIG. 4 or 5;

FIG. 7 is an enlarged plan view of part Q2 of FIG. 6;

FIG. 8 is a plan view illustrating the layout of a first color filter included in a color filter member of the light-transmitting part of the display device of FIG. 1;

FIG. 9 is a plan view illustrating the layout of a second color filter included in the color filter member of the light-transmitting part of the display device of FIG. 1;

FIG. 10 is a plan view illustrating the layout of a third color filter included in the color filter member of the light-transmitting part of the display device of FIG. 1;

FIG. 11 is a plan view illustrating the layout of first and second areas defined in the display area of the light-transmitting part of the display device of FIG. 1;

FIG. 12 is an enlarged plan view of part Q3 of FIG. 11, particularly, light-transmitting members in the first area of FIG. 11;

FIG. 13 is a cross-sectional view taken along line X3-X3′ of FIG. 12;

FIG. 14 is an enlarged plan view of part Q4 of FIG. 11, particularly, light-transmitting members near the boundary between the first and second areas of FIG. 11;

FIG. 15 is a cross-sectional view taken along line X4-X4′ of FIG. 13;

FIG. 16 is a graph showing the transmittance of light-transmitting members versus the height of the light-transmitting members or the concentration of light scatterers in the light-transmitting members;

FIGS. 17 through 22 are cross-sectional views illustrating how to fabricate the light-transmitting part of the display device of FIG. 1;

FIG. 23 is a plan view illustrating a light-transmitting part of a display device according to another embodiment of the disclosure;

FIG. 24 is a plan view illustrating light-transmitting members in a first area of a light-transmitting part of a display device according to another embodiment of the disclosure;

FIG. 25 is a cross-sectional view taken along line X5-X5′ of FIG. 24;

FIG. 26 is a cross-sectional view taken along line X6-X6′ of FIG. 24;

FIG. 27 is a plan view illustrating light-transmitting members in a first area of a light-transmitting part of a display device according to another embodiment of the disclosure and nozzles for applying a base resin and a light scatterer onto the light-transmitting member; and

FIG. 28 is a graph showing the concentration of a light scatterer applied versus the locations of the nozzles of FIG. 27.

### DETAILED DESCRIPTION

The present inventive concept will now be described more fully hereinafter with reference to the accompanying drawings, in which preferred embodiments are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Embodiments of the disclosure will hereinafter be described with reference to the attached drawings.

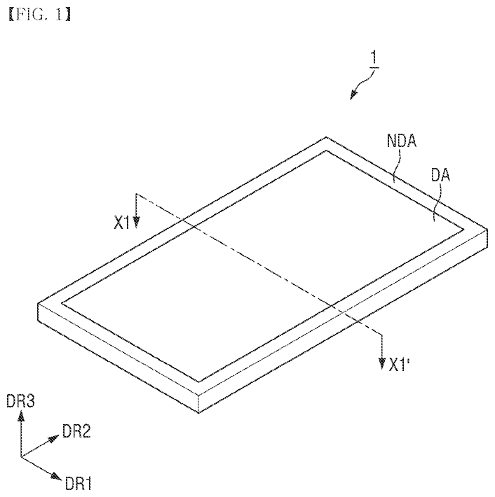

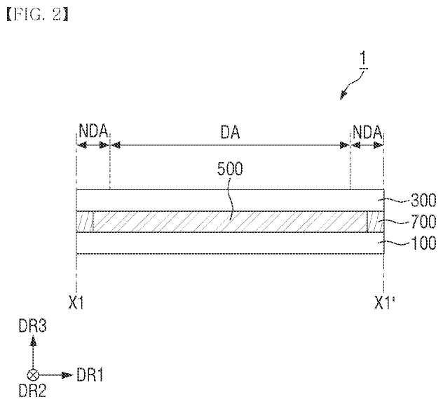

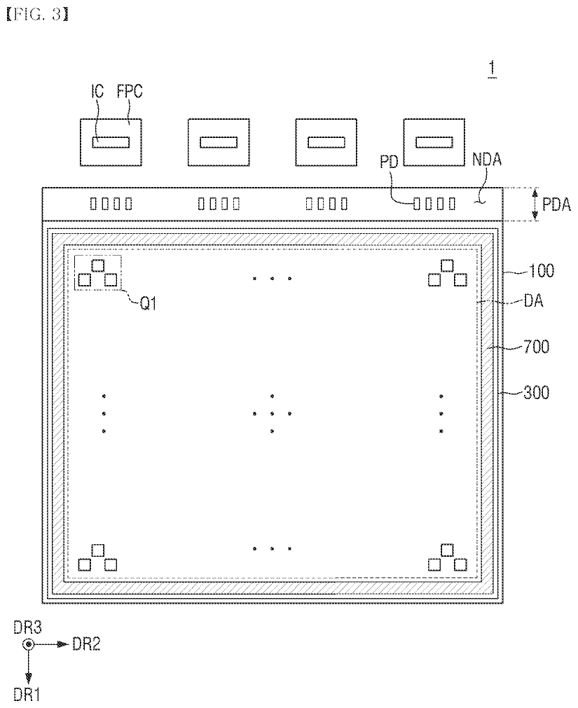

FIG. 1 is a perspective view of a display device according to an embodiment of the disclosure. FIG. 2 is a cross-sectional view of the display device of FIG. 1. FIG. 3 is a plan view of the display device of FIG. 1.

Referring to FIGS. 1 and 2, a display device 1 may be applicable to a portable electronic device such as a mobile phone, a smartphone, a tablet personal computer (PC), a mobile communication terminal, an electronic notepad, an electronic book reader, a portable multimedia player (PMP), a navigation device, or an ultramobile PC (UMPC). The display device 1 may also be applicable to a television (TV), a notebook computer, a monitor, an electronic billboard, or an Internet-of-Things (IoT) device. Obviously, the display device 1 may also be applicable to various other electronic devices without departing from the concept of the disclosure.

The display device 1 may have a three-dimensional (3D) shape. For example, the display device 1 may have a cuboid shape or a 3D shape similar to a cuboid shape. A direction parallel to a first side of the display device 1 may be referred to as a first coordinate direction DR1, a direction parallel to a second side of the display device 1 may be referred to as a second coordinate direction DR2, and the thickness direction of the display device 1 may be referred to as a third coordinate direction DR3. To distinguish one direction from another, parallel direction extending in a particular coordinate direction (e.g., DR1, DR2, DR3), one particular direction on a coordinate direction may be referred to as a first sub-direction, and the opposite, parallel direction may be referred to as a second sub-direction. FIG. 1, for example, shows the coordinate directions DR1, DR2, and DR3. The direction indicated by an arrow in each coordinate direction may be referred to as “a first sub-direction” and the opposite direction on the same coordinate direction (e.g., DR1) may be referred to as “a second sub-direction.” The first and second coordinate directions DR1 and DR2 may be perpendicular to each other, the first and third coordinate directions DR1 and DR3 may be perpendicular to each other, and the second and third coordinate directions DR2 and DR3 may be perpendicular to each other.

In some embodiments, the display device 1 may have a rectangular shape in plan view. In other words, as illustrated in FIG. 1, the display device 1 may have a rectangle-like shape having long sides extending in the second coordinate direction DR2 and short sides extending in the first coordinate direction DR1 in a plan view, but the disclosure is not limited thereto. The corners at which the long sides and the short sides of the display device 1 meet may be rounded to have a predetermined curvature or may be formed at a right angle. The planar shape of the display device 1 is not particularly limited. Alternately, the display device 1 may be formed to have a non-tetragonal polygonal shape, a circular shape, or an elliptical shape in plan view.

The display device 1 may include a display area DA, which displays an image, and a non-display area NDA, which does not display an image. The non-display area NDA may be disposed to surround the edges of the display area DA, but the disclosure is not limited thereto. An image displayed in the display area DA may be visible from a side, in the third coordinate direction DR3, of the display device 1.

The display device 1 may include a light-emitting part 100 and a light-transmitting part 300, which is opposite to the light-emitting part 100, and may further include a sealing member 700, which couples the light-emitting part 100 and the light-transmitting part 300, and a filler part 500, which fills the gap between the light-emitting part 100 and the light-transmitting part 300.

The light-emitting part 100 may include elements and circuits for displaying an image (e.g., pixel circuits such as switching elements), a pixel-defining film 170, which defines emission areas and a non-emission area in the display area DA, and self-light-emitting elements. The self-light-emitting elements may include organic light-emitting diodes (OLEDs), quantum-dot light-emitting diodes (LEDs), micro-LEDs including an inorganic material, and/or nano-LEDs including an inorganic material. For convenience, the self-light-emitting elements will hereinafter be described as being OLEDs.

The light-transmitting part 300 may be disposed above the light-emitting part 100 and may face the light-emitting part 100. In some embodiments, the light-transmitting part 300 may include color conversion patterns capable of converting the color of light incident upon the light-transmitting part 300 after being emitted from the light-emitting part 100. In some embodiments, the light-transmitting part 300 may include color filter members 320 and/or light-transmitting members. In some embodiments, the light-transmitting part 300 may include both the color filter members 320 and the light-transmitting members. As will be described later, the light-transmitting members may include wavelength conversion shifters and/or light scatterers.

The sealing member 700 may be positioned between the light-emitting part 100 and the light-transmitting part 300, in the non-display area NDA. In a plan view, the sealing member 700 may be disposed along the edges of each of the light-emitting part 100 and the light-transmitting part 300, in the non-display area NDA, to surround the display area DA. The light-emitting part 100 and the light-transmitting part 300 may be coupled together via the sealing member 700.

In some embodiments, the sealing member 700 may be formed of an organic material. For example, the sealing member 700 may be formed of an epoxy resin, but the disclosure is not limited thereto. In some embodiments, the sealing member 700 may be provided as frit including glass.

The filler part 500 may be positioned in the space between the light-emitting part 100 and the light-transmitting part 300, surrounded by the sealing member 700. The filler part 500 may fill the gap between the light-emitting part 100 and the light-transmitting part 300.

In some embodiments, the filler part 500 may be formed of a material capable of transmitting light therethrough. In some embodiments, the filler part 500 may be formed of an organic material. For example, the filler part 500 may be formed of a silicone-based organic material, an epoxy-based organic material, or the mixture thereof.

Referring to FIG. 3, the display device may further include flexible circuit boards FPC and driving chips IC. FIG. 3 depicts a display area QA that includes multiple units Q1. As will be described in more detail below, each unit Q1 includes three parts, depicted generally as three rectangles in FIG. 3. The units Q1 may be spaced apart from one another and generally be arranged in a matrix configuration on the display area DA.

The non-display area NDA of the display device 1 may include a pad area PDA, and a plurality of connection pads PD may be positioned in the pad area PDA. The pad area PDA may be defined in the light-emitting part 100. Accordingly, the connection pads PD may be disposed on the light-emitting part 100.

The flexible circuit boards FPC may be connected to the connection pads PD. The flexible circuit board FPC may electrically connect circuit boards for providing signals or power for driving the display device 1 to the light-emitting part 100.

The driving chips IC may be electrically connected to the circuit boards and may thus be provided with data and signals. In some embodiments, the driving chips IC may be data driving chips IC and may receive data control signals and image data from the circuit boards and generate and output data voltages corresponding to the image data.

In some embodiments, the driving chips IC may be mounted on the flexible circuit boards FPC. For example, the driving chips IC may be mounted on the flexible circuit boards FPC in a chip-on-film (COF) manner.

As will be described later, data voltages from the driving chips IC and power from the circuit boards may be transmitted to the pixel circuits of the light-emitting part 100 via the flexible circuit boards FPC and the connection pads PD.

A plurality of light-emitting areas defined in the light-emitting part 100 and a plurality of light-transmitting areas defined in the light-transmitting part 300 will hereinafter be described.

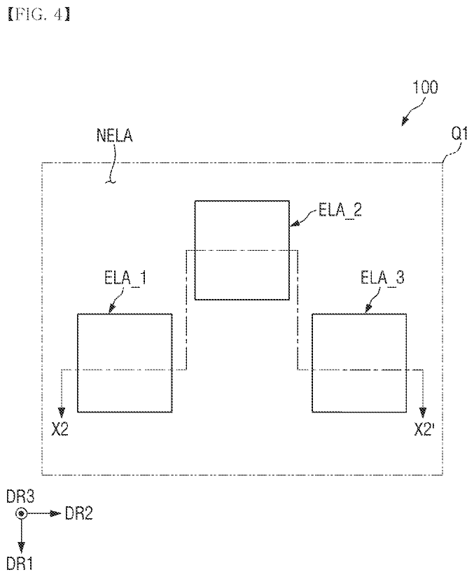

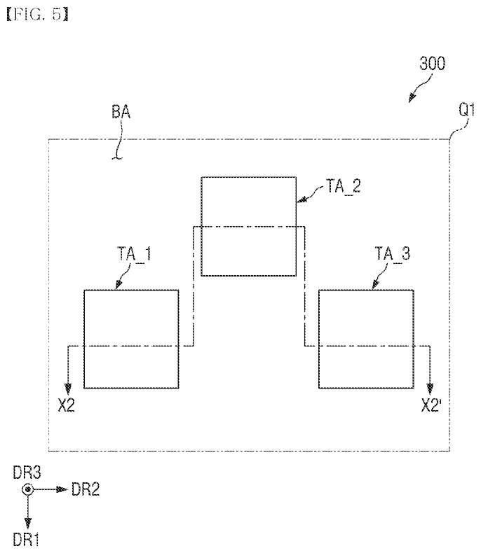

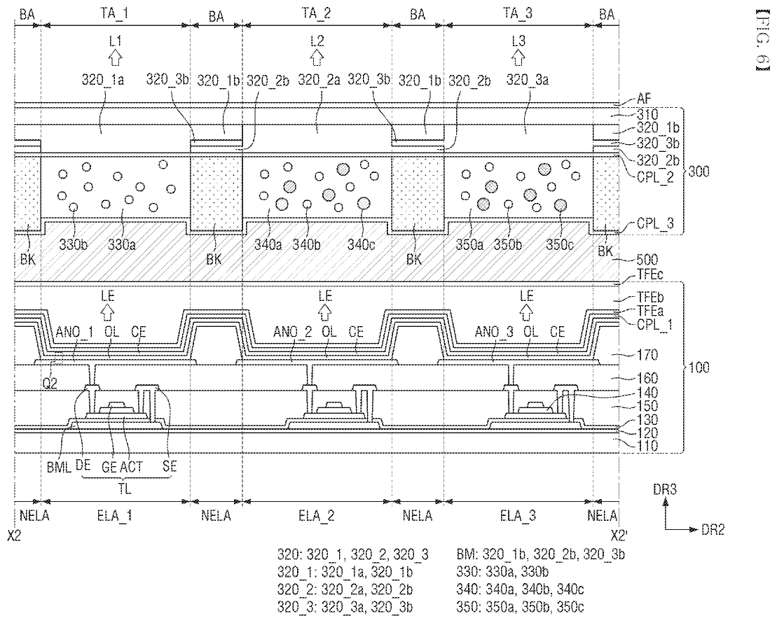

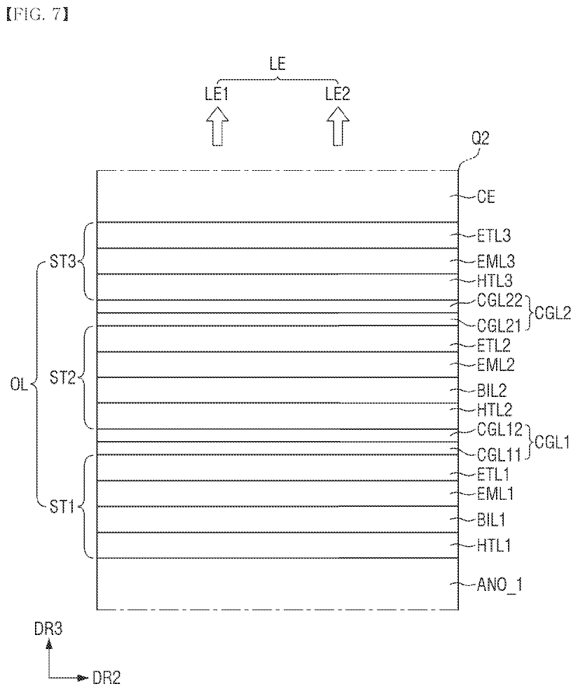

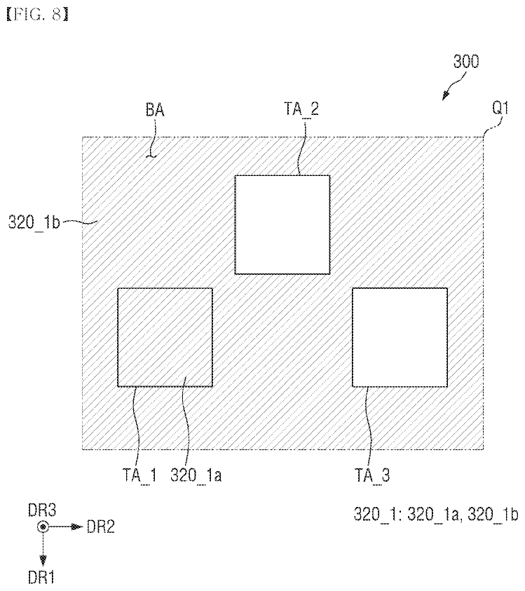

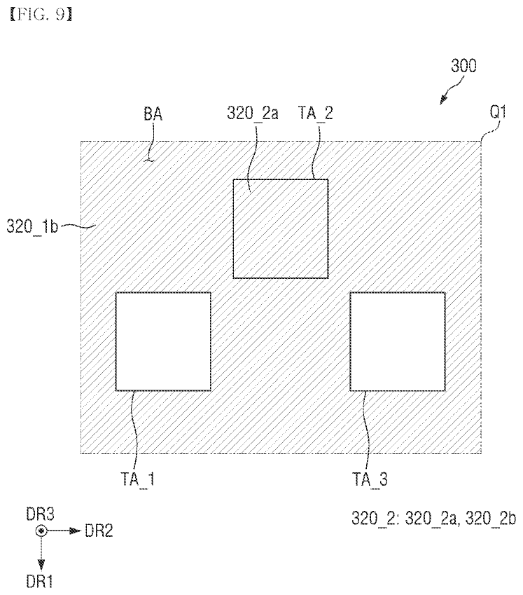

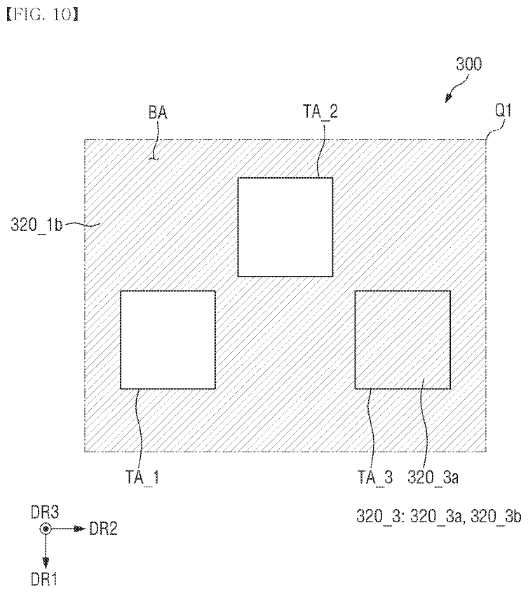

FIG. 4 is an enlarged plan view of part Q1 of FIG. 3, particularly, the light-emitting part of the display device of FIG. 1. FIG. 5 is an enlarged plan view of part Q1 of FIG. 3, particularly, the light-transmitting part of the display device of FIG. 1. FIG. 6 is a cross-sectional view taken along line X1-X1′ of FIG. 4 or 5. FIG. 7 is an enlarged plan view of part Q2 of FIG. 6. FIG. 8 is a plan view illustrating the layout of a first color filter included in a color filter member of the light-transmitting part of the display device of FIG. 1. FIG. 9 is a plan view illustrating the layout of a second color filter included in the color filter member of the light-transmitting part of the display device of FIG. 1. FIG. 10 is a plan view illustrating the layout of a third color filter included in the color filter member of the light-transmitting part of the display device of FIG. 1.

Referring to FIGS. 4 through 6 and further to FIG. 3, a plurality of light-emitting areas may be defined in the light-emitting part 100 of the display device 1, and a plurality of light-transmitting areas may be defined in the light-transmitting part 300 of the display device 1.

The display area DA and the non-display area NDA of the display device 1 may also be defined in each of the light-emitting part 100 and the light-transmitting part 300.

As illustrated in FIG. 4, first, second, and third light-emitting areas ELA_1, ELA_2, and ELA_3 may be defined in the display area DA of the light-transmitting part 100. The first, second, and third light-emitting areas ELA_1, ELA_2, and ELA_3 may be areas that output light generated by light-emitting elements in the light-emitting part 100 to the outside of the light-emitting part 100, and non-light-emitting areas NELA may be areas that do not output light to the outside of the light-emitting part 100. In some embodiments, the non-light-emitting areas NELA may surround the first, second, and third light-emitting areas ELA_1, ELA_2, and ELA_3, in the display area DA, but the disclosure is not limited thereto.

In some embodiments, the first, second, and third light-emitting areas ELA_1, ELA_2, and ELA_3 may emit first-color light. In some embodiments, the first-color light may be blue light and may have a peak wavelength of about 440 nm to about 480 nm. Here, the term “peak wavelength” refers to the wavelength at which the intensity of light reaches its maximum.

In some embodiments, as illustrated in FIG. 4, the first and third light-emitting areas ELA_1 through ELA_3 may be sequentially arranged along the second coordinate direction DR2, and the second light-emitting area ELA_2 may be disposed on first sides, in the first coordinate direction DR1, of the first and third light-emitting areas ELA_1 and ELA_3 to form a light-emitting area group together. Such light-emitting area groups may be repeatedly arranged in the display area DA along the first and second coordinate directions DR1 and DR2, as illustrated in FIG. 3. However, the disclosure is not limited to this. That is, the layout of the first, second, and third light-emitting areas ELA_1, ELA_2, and ELA_3 may vary, and alternatively, the first, second, and third light-emitting areas ELA_1, ELA_2, and ELA_3 may be sequentially arranged along the second coordinate direction DR2. For convenience, the first, second, and third light-emitting areas ELA_1, ELA_2, and ELA_3 will hereinafter be described as being arranged in the layout illustrated in FIG. 4.

In some embodiments, the first, second, and third light-emitting areas ELA_1, ELA_2, and ELA_3 may have the same size, but the disclosure is not limited thereto. Alternatively, the first, second, and third light-emitting areas ELA_1, ELA_2, and ELA_3 may have different sizes. In some embodiments, the first, second, and third light-emitting areas ELA_1, ELA_2, and ELA_3 may have a square shape in a plan view, but the disclosure is not limited thereto. For convenience, the first, second, and third light-emitting areas ELA_1, ELA_2, and ELA_3 will hereinafter be described as having a square shape in a plan view and having substantially the same size.

First, second, and third light-transmitting areas TA_1, TA_2, and TA_3 may be defined in the display area DA of the light-transmitting part 300. The first, second, and third light-transmitting areas TA_1, TA_2, and TA_3 may be areas that transmit light generated by the first, second, and third light-emitting areas ELA_1, ELA_2, and ELA_3 therethrough. Light-blocking areas BA may be positioned around the first, second, and third light-transmitting areas TA_1, TA_2, and TA_3, in the display area DA of the light-transmitting part 300. In some embodiments, the light-blocking areas BA may surround the first, second, and third light-transmitting areas TA_1, TA_2, and TA_3, but the disclosure is not limited thereto. For example, the light-blocking areas BA may be positioned not only in the display area DA, but also the non-display area NDA of the light-transmitting part 300.

When the light-emitting part 100 and the light-transmitting part 300 are combined, the first light-transmitting area TA_1 may correspond to, and overlap with, the first light-emitting area ELA_1, the second light-transmitting area TA_2 may correspond to, and overlap with, the second light-emitting area ELA_2, and the third light-transmitting area TA_3 may correspond to, and overlap with, the third light-emitting area ELA_3. The first light-transmitting area TA_1 may have substantially the same size as the first light-emitting area ELA_1 such that their edges are aligned. The second light-transmitting area TA_2 may have substantially the same size as the second light-emitting area ELA_2 such that their edges are aligned. The third light-transmitting area TA_3 may have substantially the same size as the third light-emitting area ELA_3, such that their edges are aligned. However, the disclosure is not limited to this. Alternatively, the first, second, and third light-transmitting areas TA_1, TA_2, and TA_3 may have different sizes from the first, second, and third light-emitting areas ELA_1, ELA_2, and ELA_3, respectively. However, for convenience, the first, second, and third light-transmitting areas TA_1, TA_2, and TA_3 will hereinafter be described as having substantially the same size as with the first, second, and third light-emitting areas ELA_1, ELA_2, and ELA_3, respectively such that their edges are aligned.

The first and third light-transmitting areas TA_1 and TA_3 may be sequentially arranged along the second coordinate direction DR2, and the second light-transmitting area TA_2 may be disposed on first sides, in the first coordinate direction DR1, of the first and third light-transmitting areas TA_1 and TA_3 to form a light-transmitting area group together. Such light-transmitting area groups may be repeatedly arranged in the display area DA along the first and second coordinate directions DR1 and DR2, as illustrated in FIG. 3.

First-color light provided by the light-emitting part 100 may be provided to the outside of the display device 1 through the first, second, and third light-transmitting areas TA_1, TA_2, and TA_3. Light emitted out of the display device 1 through the first light-transmitting area TA_1, light emitted out of the display device 1 through the second light-transmitting area TA_2, and light emitted out of the display device 1 through the third light-transmitting area TA_3 will hereinafter be referred to as first emitted light L1, second emitted light L2, and third emitted light L3, respectively. The first emitted light L1, the second emitted light L2, and the third emitted light L3 may be the first-color light, the second-color light, and the third-color light, respectively.

In some embodiments, the first-color light may be blue light having a peak wavelength of about 440 nm to about 480 nm, the second-color light may be green light having a peak wavelength of about 510 nm to about 550 nm, and the third-color light may be red light having a peak wavelength of about 610 nm to about 650 nm.

The structure of the display device 1 will hereinafter be described.

FIG. 6 is a cross-sectional view taken along line X1-X1′ of FIG. 4 or 5. FIG. 7 is an enlarged plan view of part Q2 of FIG. 6.

Referring to FIG. 6, the display device 1 may include the light-emitting part 100, the light-transmitting part 300, which is disposed above the light-emitting part 100, and the filler part 500, which is interposed between the light-transmitting part 100 and the light-transmitting part 300. The light-emitting part 100, the light-transmitting part 300, and the filler part 500 will hereinafter be described.

The light-emitting part 100 may have a structure in which a first substrate 110, a buffer layer 120, lower light-blocking layers BML, a first insulating layer 130, semiconductor layers ACT, gate electrodes GE, gate insulating layers 140, a second insulating layer 150, source electrodes SE and drain electrodes DE, a third insulating layer 160, light-emitting elements, a pixel-defining film 170, a first capping layer CPL_1, and a thin-film encapsulation (TFE) layer are sequentially stacked in the third coordinate direction DR3.

The first substrate 110 may form the base of the light-emitting part 100. The first substrate 110 may be formed of a material capable of transmitting light therethrough. The first substrate 110 may be a glass substrate or a plastic substrate. In a case where the first substrate 110 is a plastic substrate, the first substrate 110 may have flexibility. In some embodiments, in a case where the first substrate 110 is a plastic substrate, the first substrate 110 may include polyimide, but the disclosure is not limited thereto.

The buffer layer 120 may be disposed on the first substrate 110. The buffer layer 120 may block any foreign materials or moisture that may infiltrate into the elements disposed on the buffer layer 120, through the first substrate 110.

In some embodiments, the buffer layer 120 may include an inorganic material such as silicon oxide (SiO₂), silicon nitride (SiNₓ), or silicon oxynitride (SiON) and may be formed as a single- or multilayer film, but the disclosure is not limited thereto.

The lower light-blocking layers BML may be disposed on the buffer layer 120. The lower light-blocking layers BML may prevent external light or light emitted by the light-emitting elements from entering the semiconductor layers ACT. Accordingly, the occurrence of leakage currents in thin-film transistors (TFTs) TL can be prevented.

The lower light-blocking layers BML may be formed of a conductive material capable of blocking light. In some embodiments, the lower light-blocking layers BML may include silver (Ag), nickel (Ni), gold (Au), platinum (Pt), aluminum (Al), copper (Cu), molybdenum (Mo), titanium (Ti), neodymium (Nd), or an alloy thereof. In some embodiments, the lower light-blocking layers BML may have a single- or multilayer structure. For example, in a case where the lower light-blocking layers BML have a multilayer structure, the lower light-blocking layers BML may include a stack of Ti/Cu/indium tin oxide (ITO) or Ti/Cu/aluminum oxide (Al₂O₃), but the disclosure is not limited thereto.

In some embodiments, a plurality of lower light-blocking layers BML may be provided to correspond to, and be covered at least partially by, the semiconductor layers ACT. In some embodiments, the lower light-blocking layers BML may be wider than the width of the semiconductor layers ACT.

In some embodiments, the lower light-blocking layers BML may form parts of the wiring that electrically connects the TFTs TL of FIG. 6 to data lines, power supply lines, and other TFTs (not illustrated). In some embodiments, the lower light-blocking layers BML may be formed of a material having a lower resistance than the source electrodes SE and the drain electrodes DE.

The first insulating layer 130 may be disposed on the lower light-blocking layers BML. The first insulating layer 130 may electrically insulate the lower light-blocking layer BML and the semiconductor layers ACT. The first insulating layer 130 may cover the lower light-blocking layer BML.

In some embodiments, the first insulating layer 130 may include an inorganic material such as SiO₂, SiNₓ, SiON, Al₂O₃, titanium oxide (TiO₂), tantalum oxide (Ta₂O), hafnium oxide (HfO₂), or ZrO₂.

The semiconductor layers ACT may be disposed on the first insulating layer 130. The semiconductor layers ACT may be disposed to correspond to the first, second, and third light-emitting areas ELA_1, ELA_2, and ELA_3, in the display area DA. Also, the semiconductor layers ACT may be disposed to overlap with the lower light-blocking layer BML and may thus be able to suppress the generation of an optical current in the semiconductor layers ACT.

The semiconductor layers ACT may include an oxide semiconductor. In some embodiments, the semiconductor layers ACT may be formed of a zinc oxide-based material such as zinc oxide (ZnO), indium zinc oxide (IZO), or indium gallium zinc oxide (IGZO), but the disclosure is not limited thereto. In some embodiments, the semiconductor layers ACT may include amorphous silicon or polysilicon.

The gate electrodes GE may be disposed on the semiconductor layers ACT. The gate electrodes GE may be disposed to overlap with the semiconductor layers ACT, in the display area DA. In some embodiments, the width of the gate electrodes GE may be less than the width of the semiconductor layers ACT, but the disclosure is not limited thereto.

In some embodiments, the gate electrodes GE may include at least one of Al, Pt, palladium (Pd), Ag, magnesium (Mg), Au, Ni, Nd, iridium (Ir), chromium (Cr), lithium (Li), calcium (Ca), Mo, Ti, tungsten (W), and Cu and may be formed as single- or multilayer films, but the disclosure is not limited thereto.

The gate insulating layers 140 may be disposed between the semiconductor layers ACT and the gate electrodes GE. The gate insulating layers 140 may insulate the semiconductor layers ACT and the gate electrodes GE. In some embodiments, the gate insulating layers 140 may not be formed as a single layer on a first surface, in the third coordinate direction DR3, of the first substrate 110, but may be formed in part as patterns, and the width of the gate insulating layers 140 may be less than the width of the semiconductor layers ACT and greater than the width of the gate electrodes GE. However, the disclosure is not limited to this.

In some embodiments, the gate insulating layers 140 may include an inorganic material. For example, the gate insulating layers 140, like the first insulating layer 130, may include an inorganic material such as SiO₂, SiNₓ, SiON, Al₂O₃, TiO₂, Ta₂O, HfO₂, or ZrO₂.

The second insulating layer 150 may be disposed on the gate insulating layers 140 to cover the semiconductor layers ACT and the gate electrodes GE. In some embodiments, the second insulating layer 150 may function as a planarization film providing a flat surface.

The second insulating layer 150 may include an organic material. In some embodiments, the second insulating layer 150 may include at least one of photoacryl (PAC), polystyrene, polymethyl methacrylate (PMMA), polyacrylonitrile (PAN), polyamide, polyimide, polyarylether, a heterocyclic polymer, parylene, a fluorine-based polymer, an epoxy resin, a benzocyclobutene series resin, a siloxane resin, and a silane resin, but the disclosure is not limited thereto.

The source electrodes SE may be spaced apart from the drain electrodes DE, and the source electrodes SE and the drain electrodes DE may be disposed on the second insulating layer 150. The source electrodes SE and the drain electrodes DE may be connected to the semiconductor layers ACT through contact holes penetrating the second insulating layer 150. In some embodiments, the source electrodes SE may be connected to the lower light-blocking layers BML not only through the second insulating layer 150, but also through the first insulating layer 130. In a case where the lower light-blocking layers BML are parts of wiring that transmit signals or voltages, the source electrodes SE may be connected, and electrically coupled, to the lower light-blocking layers BML and may thus be able to receive voltages provided to the wiring. Alternatively, in a case where the lower light-blocking layers BML are floated patterns, rather than wires, voltages provided to the source electrodes SE may be transmitted to the lower light-blocking layers BML.

The source electrodes SE and the drain electrodes DE may include Al, Cu, or Ti and may be formed as multi- or single-layer films. In some embodiments, the source electrodes SE and the drain electrodes DE may have a stack of Ti/Al/Ti, but the disclosure is not limited thereto.

The semiconductor layers ACT, the gate electrodes GE, the source electrodes SE, and the drain electrodes DE may form the TFTs TL, which are switching elements. In some embodiments, the TFTs TL may be positioned in the first, second, and third light-emitting areas ELA_1, ELA_2, and ELA_3. In some embodiments, parts of the TFTs TL may be positioned in the non-light-emitting areas NELA.

The third insulating layer 160 may be disposed on the second insulating layer 150 to cover the TFTs TL. In some embodiments, the third insulating layer 160 may be a planarization film.

The third insulating layer 160 may be formed of an organic material. In some embodiments, the third insulating layer 160 may include an acrylic resin, an epoxy resin, an imide resin, or an ester resin or may include a photosensitive organic material, but the disclosure is not limited thereto.

First, second, and third anode electrodes ANO_1, ANO_2, and ANO_3 may be disposed on the third insulating layer 160, in the display area DA.

The first anode electrode ANO_1 may be disposed in the first light-emitting area ELA_1, and at least part of the first anode electrode ANO_1 may extend into the non-light-emitting areas NELA. The first anode electrode ANO_1 may be connected to the drain electrode DE of the TFT TL corresponding to the first anode electrode ANO_1 through the third insulating layer 160.

The second anode electrode ANO_2 may be disposed in the second light-emitting area ELA_2, and at least part of the second anode electrode ANO_2 may extend into the non-light-emitting areas NELA. The second anode electrode ANO_2 may be connected to the drain electrode DE of the TFT TL corresponding to the second anode electrode ANO_2 through the third insulating layer 160.

The third anode electrode ANO_3 may be disposed in the third light-emitting area ELA_3, and at least part of the third anode electrode ANO_3 may extend into the non-light-emitting areas NELA. The third anode electrode ANO_3 may be connected to the drain electrode DE of the TFT TL corresponding to the third anode electrode ANO_3 through the third insulating layer 160.

In some embodiments, the first, second, and third anode electrodes ANO_1, ANO_2, and ANO_3 may be reflective electrodes, in which case, the first, second, and third anode electrodes ANO_1, ANO_2, and ANO_3 may be metal layers including a metal such as Ag, Mg, Al, Pt, Pd, Au, Ni, Nd, Ir, or Cr. In other embodiments, the first, second, and third anode electrodes ANO_1, ANO_2, and ANO_3 may further include metal oxide layers deposited on the metal layers. The first, second, and third anode electrodes ANO_1, ANO_2, and ANO_3 may have a multilayer stack structure, for example, a double-layer structure such as ITO/Ag, Ag/ITO, ITO/Mg, or ITO/MgF or a triple-layer structure such as ITO/Ag/ITO.

The pixel-defining film 170 may be disposed on the first, second, and third anode electrodes ANO_1, ANO_2, and ANO_3. The pixel-defining film 170 may include openings, which expose the first, second, and third anode electrodes ANO_1, ANO_2, and ANO_3, and may define the first, second, and third anode electrodes ANO_1, ANO_2, and ANO_3. In other words, the first anode electrode ANO_1 may be part of the first light-emitting area ELA_1 that is not covered, but exposed by the pixel-defining film 170, the second anode electrode ANO_2 may be part of the second light-emitting area ELA_2 that is not covered, but exposed by the pixel-defining film 170, and the third anode electrode ANO_3 may be part of the third light-emitting area ELA_3 that is not covered, but exposed by the pixel-defining film 170. An area covered by the pixel-defining film 170 may be the non-light-emitting areas NELA.

The pixel-defining film 170 may overlap with the light-blocking areas BA in the third coordinate direction DR3. The pixel-defining film 170 may also overlap with bank members BK in the third coordinate direction DR3.

In some embodiments, the pixel-defining film 170 may include an organic insulating material such as an acrylic resin, an epoxy resin, a phenolic resin, a polyamide resin, a polyimide resin, an unsaturated polyester resin, a polyphenylene ether resin, a polyphenylene sulfide resin, or BCB, but the disclosure is not limited thereto.

A light-emitting layer OL of the light-emitting part 100 may be disposed on the first, second, and third anode electrodes ANO_1, ANO_2, and ANO_3. In some embodiments, the light-emitting layer OL may be in the form of a film formed continuously over the first, second, and third light-emitting areas ELA_1, ELA_2, and ELA_3 and the non-light-emitting areas NELA. In some embodiments, the light-emitting layer OL may be positioned only in the display area DA, but the disclosure is not limited thereto. In some embodiments, part of the light-emitting layer OL may be further disposed in the non-light-emitting area NDA. The light-emitting layer OL will be described later in detail.

A cathode electrode CE of the light-emitting part 100 may be disposed on the light-emitting layer OL. In some embodiments, the cathode electrode CE may be disposed on the light-emitting layer OL and may be in the form of a film formed continuously over the first, second, and third light-emitting areas ELA_1, ELA_2, and ELA_3 and the non-light-emitting areas NELA. In other words, the cathode electrode CE may completely cover the light-emitting layer OL.

The cathode electrode CE may have translucency or transparency. In a case where the cathode electrode CE has a thickness of dozens to hundreds of angstroms, the cathode electrode CE may have translucency. In some embodiments, in a case where the cathode electrode CE has translucency, the cathode electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof, for example, the mixture of Ag and Mg. Alternatively, the cathode electrode CE may include a transparent conductive oxide and may thus have transparency. In some embodiments, in a case where the cathode electrode CE has transparency, the cathode electrode CE may include tungsten oxide (WₓOₓ), TiO₂, ITO, IZO, ZnO, indium tin zinc oxide (ITZO), or magnesium oxide (MgO).

The first anode electrode ANO_1, the light-emitting layer OL, and the cathode electrode CE may form a first light-emitting element in the first light-emitting area ELA_1, the second anode electrode ANO_2, the light-emitting layer OL, and the cathode electrode CE may form a second light-emitting element in the second light-emitting area ELA_2, and the third anode electrode ANO_3, the light-emitting layer OL, and the cathode electrode CE may form a third light-emitting element in the third light-emitting area ELA_3. Each of the first, second, and third light-emitting elements may emit light as emitted light LE.

Referring to FIG. 7, the emitted light LE, which is finally emitted from the light-emitting layer OL, may be mixed light having first and second components LE1 and LE2 mixed therein. The first and second components LE1 and LE2 may have a peak wavelength of about 440 nm to about 480 nm. That is, the emitted light LE may be blue light.

In some embodiments, the light-emitting layer OL may have, for example, a tandem structure in which a plurality of light-emitting material layers are laid over one another, as illustrated in FIG. 7. For example, the light-emitting layer OL may include a first stack ST1, which includes a first light-emitting material layer EML1, a second stack ST2, which is positioned on the first stack ST1 and includes a second light-emitting material layer EML2, a third stack ST3, which is positioned on the second stack ST2 and includes a third light-emitting material layer EML3, a first charge generation layer CGL1, which is positioned between the first and second stacks ST1 and ST2, and a second charge generation layer CGL2, which is positioned between the second and third stacks ST2 and ST3. The first, second, and third stacks ST1, ST2, and ST3 may be disposed on top of one another.

The first, second, and third light-emitting material layers EML1, EML2, and EML3 may be disposed on top of one another.

In some embodiments, the first, second, and third light-emitting material layers EML1, EML2, and EML3 may all emit the first-color light, for example, blue light. The first, second, and third light-emitting material layers EML1, EML2, and EML3 may all be blue light-emitting layers and may include an organic material.

In some embodiments, at least one of the first, second, and third light-emitting material layers EML1, EML2, and EML3 may emit first blue light having a first peak wavelength, and at least another one of the first, second, and third light-emitting material layers EML1, EML2, and EML3 may emit second blue light having a second peak wavelength, which is different from the first peak wavelength. For example, one of the first, second, and third light-emitting material layers EML1, EML2, and EML3 may emit the first blue light having the first peak wavelength, and the other two light-emitting material layers may emit the second blue light having the second peak wavelength. That is, the emitted light LE, which is finally emitted from the light-emitting layer OL, may be mixed light having the first and second components LE1 and LE2 mixed therein, the first component LE1 may be the first blue light having the first peak wavelength, and the second component LE2 may be the second blue light having the second peak wavelength.

In some embodiments, one of the first and second peak wavelengths may range between 440 nm and 460 nm, and the other peak wavelength may range between 460 nm and 480 nm. However, the disclosure is not limited to this. In some embodiments, the first and second peak wavelengths may both include 460 nm. In some embodiments, one of the first blue light and the second blue light may be deep-blue light, and the other blue light may be sky-blue light.

In some embodiments, the emitted light LE may be blue light and may include long- and short-wavelength components. Thus, the light-emitting layer OL can emit blue light with a broad emission peak as the emitted light LE. Accordingly, color visibility at side viewing angles can be improved, as compared to conventional light-emitting elements emitting blue light with a sharp emission peak.

In some embodiments, each of the first, second, and third light-emitting material layers EML1, EML2, and EML3 may include a host and a dopant. The material of the host is not particularly limited. For example, tris(8-hydroxyquinolino)aluminum (Alq₃), 4,4′-bis(N-carbazolyl)-1,1′-biphenyl (CBP), poly(n-vinylcarbazole) (PVK), 9,10-di(naphthalene yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN) may be used as the host.

For example, the first, second, and third light-emitting material layers EML1, EML2, and EML3, which emit blue light, may include a fluorescent material selected from the group consisting of spiro-DPVBi, spiro-6P, distyryl benzene (DSB), distyryl arylene (DSA), a polyfluorene (PFO)-based polymer, and poly(p-phenylene vinylene (PPV). In another example, the first, second, and third light-emitting material layers EML1, EML2, and EML3 may include a phosphorescent material including an organometallic complex such as (4,6-F2ppy)₂Irpic.

As already mentioned above, at least one of the first, second, and third light-emitting material layers EML1, EML2, and EML3 may emit blue light having a different wavelength range from at least another one of the first, second, and third light-emitting material layers EML1, EML2, and EML3. To emit blue light of different wavelength ranges, the first, second, and third light-emitting material layers EML1, EML2, and EML3 may include the same material, and a method of controlling a resonance distance may be used. Alternatively, to emit blue light of different wavelength ranges, at least two of the first, second, and third light-emitting material layers EML1, EML2, and EML3 may include different materials.

However, the disclosure is not limited to this. Alternatively, the first, second, and third light-emitting material layers EML1, EML2, and EML3 may all emit blue light having a peak wavelength of 440 nm to 480 nm and may be formed of the same material.

Alternatively, one of the first, second, and third light-emitting material layers EML1, EML2, and EML3 may emit the first blue light having the first peak wavelength, another one of the first, second, and third light-emitting material layers EML1, EML2, and EML3 may emit the second blue light having the second peak wavelength, which is different from the first peak wavelength, and the other light-emitting material layer may emit third blue light having a third peak wavelength, which is different form the first and second peak wavelengths. In some embodiments, one of the first, second, and third peak wavelengths may range between 440 nm and 460 nm, and another one of the first, second, and third peak wavelengths may range between 460 nm and 470 nm, and the other peak wavelength may range between 470 nm and 480 nm.

In some embodiments, the emitted light LE, which is emitted from the light-emitting layer OL, may be blue light and may include long-, intermediate-, and short-wavelength components. Thus, the light-emitting layer OL can emit blue light having a broad emission peak as the emitted light LE and can improve color visibility at side viewing angles.

The light-emitting elements of the display device 1 can improve an optical efficiency as compared to conventional light-emitting elements not employing a tandem structure in which multiple light-emitting material layers are stacked, and can lengthen the life of the display device 1.

Alternatively, at least one of the first, second, and third light-emitting material layers EML1, EML2, and EML3 may emit the third-color light, for example, blue light, and at least another one of the first, second, and third light-emitting material layers EML1, EML2, and EML3 may emit the second-color light, for example, green light. The peak wavelength of blue light emitted by at least one of the first, second, and third light-emitting material layers EML1, EML2, and EML3 may range between 440 nm and 480 nm or between 460 nm and 480 nm, and the peak wavelength of green light emitted by at least another one of the first, second, and third light-emitting material layers EML1, EML2, and EML3 may range between 510 nm and 550 nm.

For example, one of the first, second, and third light-emitting material layers EML1, EML2, and EML3 may be a green light-emitting layer emitting green light, and the other two light-emitting material layers may be blue light-emitting layers emitting blue light. In this example, the peak wavelength range of blue light emitted by one of the two blue light-emitting layers may coincide with, or differ from, the peak wavelength range of blue light emitted by the other blue light-emitting layer.

Alternatively, the emitted light LE, which is emitted from the light-emitting layer OL, may be mixed light having the first and second components LE1 and LE2 mixed therein, and the first and second components LE1 and LE2 may be blue light and green light, respectively. For example, in a case where the first and second components LE1 and LE2 are deep-blue light and green light, respectively, the emitted light LE may be sky-blue light. The emitted light LE, which is emitted from the light-emitting layer OL, may be the mixture of blue light and green light and may include long- and short-wavelength components. Thus, the light-emitting layer OL can emit blue light with a broad emission peak as the emitted light LE and can improve color visibility at side viewing angles. Also, as the second component LE2 of the emitted light LE is green light, the green-light component of light to be emitted out of the display device 1 can be compensated for, and as a result, the color reproducibility of the display device 1 can be improved.

In some embodiments, a green light-emitting layer among the first, second, and third light-emitting material layers EML1, EML2, and EML3 may include a host and a dopant. The material of the host of the green-light emitting layer is not particularly limited. The host of the green light-emitting layer may include, for example, Alq₃, 4,4′-bis(N-carbazolyl)-1,1′-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBi), 3-tert-butyl-9,10-di(naphth yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN).

The dopant of the green-light emitting layer may include, for example, a fluorescent material containing Alq₃ or a phosphorescent material such as fac-tris(2-phenylpyridine)iridium (Ir(ppy)₃), bis(2-phenylpyridine)(acetylacetonate)iridium(III) (Ir(ppy)₂(acac)), or 2-phenyl-4-methyl-pyridine iridium (Ir(mpyp)₃).

The first charge generation layer CGL1 may be located between the first and second stacks ST1 and ST2. The first charge generation layer CGL1 may inject electric charge into the light-emitting layer OL. The first charge generation layer CGL1 may balance electric charge between the first and second stacks ST1 and ST2. The first charge generation layer CGL1 may include an n-type charge generation layer CGL11 and a p-type charge generation layer CGL12. The p-type charge generation layer CGL12 may be disposed on the n-type charge generation layer CGL11 and may be located between the n-type charge generation layer CGL11 and the second stack ST2.

The first charge generation layer CGL1 may have a structure in which the n-type charge generation layer CGL11 and the p-type charge generation layer CGL12 are bonded together. The n-type charge generation layer CGL11 may be disposed closer to the first anode electrode ANO_1 than to the cathode electrode CE. The p-type charge generation layer CGL12 may be disposed closer to the cathode electrode CE than to the first anode electrode ANO_1. The n-type charge generation layer CGL11 may provide electrons the first light-emitting material layer EML1, which is adjacent to the first anode electrode ANO_1, and the p-type charge generation layer CGL12 may provide holes to the second light-emitting material layer EML2, which is included in the second stack ST2. As the first charge generation layer CGL1 is disposed between the first and second stacks ST1 and ST2 and provides charge to the light-emitting layer OL, an emission efficiency can be improved, and a driving voltage can be lowered.

The first stack ST1 may be positioned on the first, second, and third anode electrodes ANO_1, ANO_2, and ANO_3 and may further include a first hole transport layer HTL1, a first electron blocking layer BILL and a first electron transport layer ETL1.

The first hole transport layer HTL1 may be positioned on the first, second, and third anode electrodes ANO_1, ANO_2, and ANO_3. The first hole transport layer HTL1 may facilitate the transport of holes and may include a hole transport material. The hole transport material may include a carbazole derivative such as N-phenylcarbazole or polyvinylcarbazole, a fluorene derivative, a triphenylamine derivative such as N,N-bis(3-methylphenyl)-N,N′-diphenyl-[1,1-biphenyl]-4,4′-diamine (TPD) or TCTA, N,N′-di(1-naphthyl)-N,N′-diphenylbenzidine (NPB), or 4,4′-Cyclohexylidene bis[N,N-bis(4-methylphenyl)benzenamine] (TAPC), but the disclosure is not limited thereto.

The first electron blocking layer BIL1 may be positioned on the first hole transport layer HTL1, between the first hole transport layer HTL1 and the first light-emitting material layer EML1. The first electron blocking layer BIL1 may include a hole transport material and a metal (or a metal compound) to prevent electrons generated in the first light-emitting material layer EML1 from spilling over to the first hole transport layer HTL1. In some embodiments, the first hole transport layer HTL1 and the first electron blocking layer BIL1 may be incorporated into a single layer.

The first electron transport layer ETL1 may be positioned on the first light-emitting material layer EML1, between the first charge generation layer CGL1 and the first light-emitting material layer EML1. In some embodiments, the first electron transport layer ETL1 may include an electron transport material such as Alq₃, TPBi, 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), (2-(4-Biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum) (BAlq), berylliumbis(benzoquinolin-10-olate) (Bebq2), AND, or a mixture thereof, but the disclosure is not limited thereto. The second stack ST2 may be positioned on the first charge generation layer CGL1 and may further include a second hole transport layer HTL2, a second electron blocking layer BIL2, and a second electron transport layer ETL2.

The second hole transport layer HTL2 may be positioned on the first charge generation layer CGL1. The second hole transport layer HTL2 may be formed of the same material as the first hole transport layer HTL1 and may include at least one selected from among the above-described exemplary materials that may be included in the first hole transport layer HTL1. The second hole transport layer HTL2 may be formed as a single- or multilayer film.

The second electron blocking layer BIL2 may be positioned on the second hole transport layer HTL2, between the second hole transport layer HTL2 and the first light-emitting material layer EML1. The second electron blocking layer BIL2 may be formed of the same material as, and have the same structure as, the first electron blocking layer BIL1 and may include at least one selected from among the above-described exemplary materials that may be included in the first electron blocking layer BIL1.

The second electron transport layer ETL2 may be positioned on the second light-emitting material layer EML2, between the second charge generation layer CGL2 and the second light-emitting material layer EML2. The second electron transport layer ETL2 may be formed of the same material as, and have the same structure as, the first electron transport layer ETL1 and may include at least one selected from among the above-described exemplary materials that may be included in the first electron transport layer ETL1. The second electron transport layer ETL2 may be formed as a single- or multilayer film.

The second charge generation layer CGL2 may be positioned on the second stack ST2, between the second and third stacks ST2 and ST3.

The second charge generation layer CGL2 may have the same structure as the first charge generation layer CGL1. For example, the second charge generation layer CGL2 may include an n-type charge generation layer CGL21, which is adjacent to the second stack ST2, and a p-type charge generation layer CGL22, which is adjacent to the cathode electrode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are bonded together. The first and second charge generation layers CGL1 and CGL2 may be formed of different materials or of the same material.

The second stack ST2 may be positioned on the second charge generation layer CGL2 and may further include a third hole transport layer HTL3 and a third electron transport layer ETL3.

The third hole transport layer HTL3 may be positioned on the second charge generation layer CGL2. The third hole transport layer HTL3 may be formed of the same material as the first hole transport layer HTL1 or may include at least one selected from among the above-described exemplary materials that may be included in the first hole transport layer HTL1. The third hole transport layer HTL3 may be formed as a single- or multilayer film. In a case where the third hole transport layer HTL3 consists of multiple layers, the multiple layers may include different materials.

The third electron transport layer ETL3 may be positioned on the third light-emitting material layer EML3, between the cathode electrode CE and the third light-emitting material layer EML3. The third electron transport layer ETL3 may be formed of the same material as, and have the same structure as, the first electron transport layer ETL1 and may include at least one selected from among the above-described exemplary materials that may be included in the first electron transport layer ETL1. The third electron transport layer ETL3 may be formed as a single- or multilayer film. In a case where the third electron transport layer ETL3 consists of multiple layers, the multiple layers may include different materials.

Although not specifically illustrated, a hole injection layer may be further positioned between the first stack ST1 and the first anode electrode ANO_1, between the second and third anode electrodes ANO_2 and ANO_3, between the second stack ST2 and the first charge generation layer CGL1, and/or between the third stack ST3 and the second charge generation layer CGL2. The hole injection layer may facilitate the injection of holes into the first, second, and third light-emitting material layers EML1, EML2, and EML3. In some embodiments, the hole injection layer may be formed of at least one selected from the group consisting of copper phthalocyanine (CuPc), poly(3,4)-ethylenedioxythiophene (PEDOT), polyaniline (PANT), and N,N-dinaphthyl-N,N′-diphenyl benzidine (NPD), but the disclosure is not limited thereto. In some embodiments, multiple hole injection layers may be positioned between the first stack ST1 and the first anode electrode ANO_1, between the second and third anode electrodes ANO_2 and ANO_3, between the second stack ST2 and the first charge generation layer CGL1, and between the third stack ST3 and the second charge generation layer CGL2.

Although not specifically illustrated, an electron injection layer may be further positioned between the third electron transport layer ETL3 and the cathode electrode CE, between the second charge generation layer CGL2 and the second stack ST2, and/or between the first charge generation layer CGL1 and the first stack ST1. The electron injection layer may facilitate the injection of electrons and may be formed of Alq₃, PBD, TAZ, Spiro-PBD, BAlq, or SAlq, but the disclosure is not limited thereto. Also, the electron injection layer may include a metal halide compound, for example, at least one selected from the group consisting of MgF₂, LiF, NaF, KF, RbF, CsF, FrF, LiI, NaI, KI, RbI, CsI, FrI, and CaF₂, but the disclosure is not limited thereto. Also, the electron injection layer may include a lanthanum (La)-based material such as Yb, Sm, or Eu or may include both a metal halide material such as RbI:Yb or KI:Yb and the La-based material. In a case where the electron injection layer includes both the metal halide material and the La-based material, the electron injection layer may be formed by co-depositing the metal halide material and the La-based material. In some embodiments, multiple electron injection layers may be positioned between the third electron transport layer ETL3 and the cathode electrode CE, between the second charge generation layer CGL2 and the second stack ST2, and between the first charge generation layer CGL1 and the first stack ST1.

In some embodiments, the light-emitting layer OL may not include a red light-emitting material layer and thus may not emit the third-color light, for example, red light. In other words, the emitted light LE may not include a component with a peak wavelength of about 610 nm to about 650 nm and may include only a component with a peak wavelength of about 440 nm to about 550 nm.

Referring again to FIG. 6, the first capping layer CPL_1 may be disposed on the cathode electrode CE. The first capping layer CPL_1 may improve viewing angle characteristics and increase external emission efficiency. The first capping layer CPL_1 may be disposed in common in the first, second, and third light-emitting areas ELA_1, ELA_2, and ELA_3 and the non-light-emitting areas NELA. The first capping layer CPL_1 may completely cover the cathode electrode CE.

The first capping layer CPL_1 may include at least one of an inorganic material having light transmittance and an organic material. In other words, the first capping layer CPL_1 may be formed as an inorganic layer, an organic layer, or an organic layer including inorganic particles. In some embodiments, the first capping layer CPL_1 may include a triamine derivative, a carbazole derivative, an arylene diamine derivative, or an Alq₃, but the disclosure is not limited thereto.

The TFE layer of the light-emitting part 100 may be disposed on the first capping layer CPL_1. The TFE layer may protect the underlying layers from an external foreign material such as moisture. The TFE layer may be disposed in common in the first, second, and third light-emitting areas ELA_1, ELA_2, and ELA_3 and the non-light-emitting areas NELA. The TFE layer may completely cover the first capping layer CPL_1.

The TFE layer may include a lower inorganic layer TFEa, an organic layer TFEb, and an upper inorganic layer TFEc, which are stacked on the first capping layer CPL_1.

The lower inorganic layer TFEa may completely cover the first capping layer CPL_1, in the display area DA, and may cover the first, second, and third light-emitting elements.

The organic layer TFEb may be disposed on the lower inorganic layer TFEa and may cover the first, second, and third light-emitting elements.

The upper inorganic layer TFEc may be disposed on the organic layer TFEb to completely cover the organic layer TFEb.

In some embodiments, the lower inorganic layer TFEa and the upper inorganic layer TFEc may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride, but the disclosure is not limited thereto.

In some embodiments, the organic layer TFEb may be formed of an acrylic resin, a methacrylic resin, polyisoprene, a vinyl resin, an epoxy resin, a urethane resin, a cellulose resin, or a perylene resin, but the disclosure is not limited thereto.

The light-transmitting part 300 may have a structure in which a second substrate 310, the color filter members 320, a second capping layer CPL_2, the bank members BK, the light-transmitting members, and a third capping layer CPL_3 are sequentially stacked in the third coordinate direction DR3.

The light-transmitting part 300 will hereinafter be described with reference to FIGS. 6 and 8 through 10.

FIG. 8 is a plan view illustrating the layout of a first color filter included in the color filter member of the light-transmitting part of the display device of FIG. 1. FIG. 9 is a plan view illustrating the layout of a second color filter included in the color filter member of the light-transmitting part of the display device of FIG. 1. FIG. 10 is a plan view illustrating the layout of a third color filter included in the color filter member of the light-transmitting part of the display device of FIG. 1.

Referring to FIGS. 8 through 10, the light-transmitting part 300 may have a structure in which the second substrate 310, the color filter members 320, the second capping layer CPL_2, the bank members BK, the light-transmitting members, and the third capping layer CPL_3 are sequentially stacked in the third coordinate direction DR3.

The second substrate 310 may form the base of the light-transmitting part 300. The second substrate 310 may be formed of a material capable of transmitting light therethrough. The second substrate 310 may be a glass substrate or a plastic substrate. In a case where the second substrate 310 is a plastic substrate, the second substrate 310 may have flexibility. In some embodiments, in a case where the second substrate 310 is a plastic substrate, the second substrate 310 may include polyimide, but the disclosure is not limited thereto. As the light-emitting part 100 and the light-transmitting part 300 are opposite to each other in the third coordinate direction DR3, the first substrate 110 of the light-emitting part 100 and the third substrate 310 of the light-transmitting part 300 may also be opposite to each other in the third coordinate direction DR3.

The color filter members 320 may be disposed on a second side, in the third coordinate direction DR3, of the second substrate 310, between the second substrate 310 and the light-emitting part 100. The color filter members 320 may include filtering pattern areas and a light-blocking pattern part BM. The light-blocking pattern part BM may surround the filtering pattern areas. The filtering pattern areas of the color filter members 320 may define the first, second, and third light-transmitting areas TA_1, TA_2, and TA_3 of the light-transmitting part 300, and the light-blocking pattern pat BM may define the light-blocking areas BA of the light-transmitting part 300.

As illustrated in FIGS. 6 and 8 through 10, the color filter members 320 may include first, second, and third color filters 320_1, 320_2, and 320_3. The first color filter 320_1 may absorb both the second-color light and the third-color light, but not the first-color light, the second color filter 320_2 may absorb both the first-color light and the third-color light, but not the second-color light, and the third color filter 320_3 may absorb both the first-color light and the second-color light, but not the third-color light. In other words, the first color filter 320_1 may transmit the first-color light therethrough, the second color filter 320_2 may transmit the second-color light therethrough, and the third color filter 320_3 may transmit the third-color light therethrough.

In some embodiments, the first color filter 320_1 may be a blue filter and may include a blue colorant. The term “colorant”, as used herein, encompasses both a dye and a pigment. The first color filter 320_1 may further include a base resin, and the blue colorant may be dispersed in the base resin. In some embodiments, the second color filter 320_2 may be a green filter and may include a green colorant. The second color filter 320_2 may further include a base resin, and the green colorant may be dispersed in the base resin. In some embodiments, the third color filter 320_3 may be a red filter and may include a red colorant. The third color filter 320_3 may further include a base resin, and the red filter may be dispersed in the base resin.

The first color filter 320_1 may include a first filtering pattern area 320_1a and a first light-blocking pattern area 320_1b, which surrounds the first filtering pattern area 320_1a, the second color filter 320_2 may include a second filtering pattern area 320_2a and a second light-blocking pattern area 320_2b, which surrounds the second filtering pattern area 320_2a, and the third color filter 320_3 may include a third filtering pattern area 320_3a and a third light-blocking pattern area 320_3b, which surrounds the third filtering pattern area 320_3a. Specifically, the first filtering pattern area 320_1a may overlap with the first light-transmitting area TA_1, and the first light-blocking pattern area 320_1b may surround the first filtering pattern area 320_1a and may overlap with the light-blocking areas BA, but not with the second and third light-transmitting areas TA_2 and TA_3. The second filtering pattern area 320_2a may overlap with the second light-transmitting area TA_2, and the second light-blocking pattern area 320_2b may surround the second filtering pattern area 320_2a and may overlap with the light-blocking areas BA, but not with the first and third light-transmitting areas TA_1 and TA_3. The third filtering pattern area 320_3a may overlap with the third light-transmitting area TA_3, and the third light-blocking pattern area 320_3b may surround the third filtering pattern area 320_3a and may overlap with the light-blocking areas BA, but not with the first and second light-transmitting areas TA_1 and TA_2. In other words, the filtering pattern areas of the color filter members 320 may include the first, second, and third filtering pattern areas 320_1a, 320_2a, and 320_3a of the first, second, and third color filters 320_1, 320_2, and 320_3, and the light-blocking pattern part BM may have a structure in which the first, second, and third light-blocking pattern areas 320_1b, 320_2b, and 320_3b of the first, second, and third color filters 320_1, 320_2, and 320_3 are stacked.

The first filtering pattern area 320_1a of the first color filter 320_1 may function as a blocking filter for blocking red light and green light. Specifically, the first filtering pattern area 320_1a may selectively transmit the first-color light (e.g., blue light) therethrough and may block or absorb the second-color light (e.g., green light) and the third-color light (e.g., red light).

The second filtering pattern area 320_2a of the second color filter 320_2 may function as a blocking filter for blocking blue light and red light. Specifically, the second filtering pattern area 320_2a may selectively transmit the second-color light (e.g., green light) therethrough and may block or absorb the first-color light (e.g., blue light) and the third-color light (e.g., red light).

The third filtering pattern area 320_3a of the first color filter 320_3 may function as a blocking filter for blocking blue light and green light. Specifically, the third filtering pattern area 320_3a may selectively transmit the third-color light (e.g., red light) therethrough and may block or absorb the first-color light (e.g., blue light) and the second-color light (e.g., green light).

In some embodiments, the light-blocking pattern part BM may have a structure in which the first light-blocking pattern area 320_1b, the third light-blocking pattern area 320_3b, and the second light-blocking pattern area 320_2b are sequentially stacked in the third coordinate direction DR3, but the disclosure is not limited thereto. For example, the light-blocking pattern part BM may not consist of the first, second, and third color filters 320_1, 320_2, and 320_3, but may be formed of an organic light-blocking material by coating and exposing the organic light-blocking material. For convenience, the light-blocking pattern part BM will hereinafter be described as having a structure in which the first light-blocking pattern area 320_1b, the third light-blocking pattern area 320_3b, and the second light-blocking pattern area 320_2b are sequentially stacked in the third coordinate direction DR3. The light-blocking pattern part BM may be able to absorb all the first-color light, the second-color light, and the third-color light.

The second capping layer CPL_2 may be disposed on surfaces of the color filter members 320 to cover the color filter members 320. The second capping layer CPL_2 may prevent external impurities such as moisture or the air from infiltrating into the color filter members 320 to damage the light-blocking pattern part BM and the filtering pattern areas of the color filter members 320.

The second capping layer CPL_2 may include an inorganic material. In some embodiments, the second capping layer CPL_2 may include silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride, but the disclosure is not limited thereto.

The bank members BK may be disposed on a second surface, in the third coordinate direction DR3, of the second capping layer CPL_2 and may be spaced apart from one another in the second coordinate direction DR2 to accommodate the light-transmitting members therebetween. That is, the bank members BK may define space in which to arrange the light-transmitting members. The bank members BK may be in direct contact with the second surface, in the third coordinate direction DR2, of the second capping layer CPL_2. The bank members BK may surround the light-transmitting members in plan view. The bank members BK may be disposed to overlap with the non-light-emitting areas NELA of the light-emitting part 100 and the light-blocking areas BA of the light-transmitting part 300. The bank members BK may not overlap with the first, second, and third light-emitting areas ELA_1, ELA_2, and ELA_3 of the light-emitting part 100 and the first, second, and third light-transmitting areas TA_1, TA_2, and TA_3 of the light-transmitting part 300.

In some embodiments, the bank members BK may include a photocurable organic material or a photocurable light-blocking organic material, but the disclosure is not limited thereto.

The width of the bank members BK may vary from one location to another location in the display area DA of the light-transmitting part 300, and this will be described later. As used herein, “width” refers to the measurement taken in the second coordinate direction DR2, “length” refers to the measurement taken in the first coordinate direction DR1, and “height” refers to the measurement taken in the third coordinate direction DR3 when referring to physical parts of the display device 1.

The light-transmitting members of the light-transmitting part 300 may be disposed on the second surface, in the third coordinate direction DR3, of the second capping layer CPL_2, in gaps between the bank members BK. The light-transmitting members may include a first light-transmitting member 330, which overlaps with the first light-transmitting area TA_1, a second light-transmitting member 340, which overlaps with the second light-transmitting area TA_2, and a third light-transmitting member 350, which overlaps with the third light-transmitting area TA_3. The first, second, and third light-transmitting members 330, 340, and 350 may be disposed in the display area DA of the light-transmitting part 300.

The first light-transmitting member 330 may be disposed in space defined by the bank members BK. The first light-emitting area ELA_1 and the first light-transmitting area TA_1 may overlap with each other in the third coordinate direction DR3. The first light-transmitting member 330 may be in direct contact with the second capping layer CPL_2 and the bank members BK.

The width and the height of the first light-transmitting member 330 may vary from one location to another location in the display area DA of the light-transmitting part 300, and this will be described later.

The first light-transmitting member 330 may be a light-transmitting pattern transmitting incident light therethrough. Specifically, emitted light LE provided by the first light-emitting element may be blue light and may be emitted out of the display device 1 through the first light-transmitting member 330 and the first filtering pattern area 320_1a of the first color filter 320_1. In other words, first emitted light L1, which is emitted from the first light-emitting area ELA_1 through the first light-transmitting area TA_1, may be blue light.

A first base resin 330a may be formed of an organic material with high light transmittance. In some embodiments, the first base resin 330a may include an organic material such as an epoxy resin, an acrylic resin, a cardo resin, or an imide resin, but the disclosure is not limited thereto.

A first light scatterer 330b may have a different refractive index from the first base resin 330a and may form an optical interface with the first base resin 330a. The first light scatterer 330b may include light-scattering particles. The first light scatterer 330b may scatter light in random directions, regardless of the incident angle of light, without substantially changing the wavelength of light passing through the first light-transmitting area TA_1.

The first light scatterer 330b, which is a material capable of scattering at least some of emitted light, may include particles of a metal oxide or particles of an organic material. In some embodiments, the first light scatterer 330b may include TiO₂, ZrO₂, Al₂O₃, indium oxide (In₂O₃), ZnO, or tin oxide (SnO₂) as the metal oxide or may include an acrylic resin or a urethane resin as the organic material, but the disclosure is not limited thereto.

The width of the first light-transmitting member 330 may vary from one location to another location in the display area DA of the light-transmitting part 300, and this will be described later.

The second light-transmitting member 340 may be disposed in space defined by the bank members BK. The second light-emitting area ELA_2 and the second light-transmitting area TA_2 may overlap with each other in the third coordinate direction DR3. The second light-transmitting member 340 may be in direct contact with the second capping layer CPL_2 and the bank members BK.

The second light-transmitting member 340 may be a wavelength-shifting pattern capable of converting or shifting the peak wavelength of incident light into another particular peak wavelength. Specifically, emitted light LE provided by the second light-emitting element may be blue light and may be converted into green light having a peak wavelength of about 510 nm to about 550 nm after passing through the second light-transmitting member 340 and the second filtering pattern area 320_2a of the second color filter 320_2, and the green light may be emitted out of the display device 1. In other words, the second emitted light L2, which is emitted from the second light-emitting area ELA_2 through the second light-transmitting area TA_2, may be green light.

The second light-transmitting member 340 may include a second base resin 340a, a second light scatterer 340b, which is dispersed in the second base resin 340a, and a first wavelength shifter 340c, which is also dispersed in the second base resin 340a. The second base resin 340a may be substantially the same as, or similar to, the first base resin 330a of the first light-transmitting member 330, and thus, a detailed description thereof will be omitted. The second light scatterer 340b may be substantially the same as, or similar to, the first light scatterer 330b of the first light-transmitting member 330, and thus, a detailed description thereof will be omitted. The first wavelength shifter 340c will hereinafter be described.

The first wavelength shifter 340c may convert or shift the peak wavelength of incident light into another particular peak wavelength. The first wavelength shifter 340c may convert the emitted light LE provided by the second light-emitting element, for example, blue light, into red light having a single peak wavelength of about 510 nm to about 550 nm and may emit the red light.

In some embodiments, the first wavelength shifter 340c may include quantum dots, quantum rods, or a phosphor, but the disclosure is not limited thereto. For convenience, the first wavelength shifter 340c will hereinafter be described as including, for example, quantum dots. The quantum dots may be a particulate material that emits light of a particular color in response to the electrons transitioning from the conduction band to the valance band. The quantum dots may be a semiconductor nanocrystal material. Since the quantum dots have a predetermined band gap depending on their composition and size, the quantum dots absorb light and emit light of a predetermined wavelength. The semiconductor nanocrystal material include a group IV element, a group II-VI compound, a group III-V compound, a group IV-VI compound, and a combination thereof.

The group II-VI compound may be selected from the group consisting of: a binary compound selected from among CdSe, CdTe, ZnS, ZnSe, ZnTe, ZnO, HgS, HgSe, HgTe, MgSe, MgS, and a mixture thereof; a ternary compound selected from among InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; or a quaternary compound selected from among HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from the group consisting of: a binary compound selected from among GaN, GaP, GaAs, GaSb, AlN, AlP, AlAs, AlSb, InN, InP, InAs, InSb, and a mixture thereof; a ternary compound selected from among GaNP, GaNAs, GaNSb, GaPAs, GaPSb, AlNP, AINAs, AlNSb, AlPAs, AlPSb, InGaP, InNP, InAlP, InNAs, InNSb, InPAs, InPSb, GaAlNP, and a mixture thereof; and a quaternary compound selected from among GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group IV-VI compound may be selected from the group consisting of: a binary compound selected from among SnS, SnSe, SnTe, PbS, PbSe, PbTe, and a mixture thereof; a ternary compound selected from among SnSeS, SnSeTe, SnSTe, PbSeS, PbSeTe, PbSTe, SnPbS, SnPbSe, SnPbTe, and a mixture thereof; and a quaternary compound selected from among SnPbSSe, SnPbSeTe, SnPbSTe, and a mixture thereof. The group IV element may be selected from the group consisting of Si, Ge, and a mixture thereof. The group IV compound may be a binary compound selected from among SiC, SiGe, and a mixture thereof.

Here, the binary, ternary, or quaternary compounds may exist in a uniform concentration or in a partially different concentration in particles. The quantum dots may have a core-shell structure in which one quantum dot surrounds another quantum dot. The interfaces between the cores and the shells of the quantum dots may have a concentration gradient in which the concentration of the element(s) in the shells of the quantum dots decreases toward the centers of the shells of the quantum dots.

In some embodiments, the quantum dots may have a core-shell structure consisting of a core including the above-described semiconductor nanocrystal material and a shell surrounding the core. The shells of the quantum dots may serve as protective layers for maintaining the semiconductor characteristics of the quantum dots by preventing chemical denaturation of the cores of the quantum dots and/or as charging layers for imparting electrophoretic characteristics to the quantum dots. The shells of the quantum dots may have a single-layer structure or a multilayer structure. The interfaces between the cores and the shells of the quantum dots may have a concentration gradient in which the concentration of the element(s) at the shells of the quantum dots decreases toward the centers of the shells of the quantum dots. The shells of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO or a ternary compound such as MgAl₂O₄, CoFe₂O₄, NiFe₂O₄, or CoMn₂O₄, but the disclosure is not limited thereto.

For example, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the disclosure is not limited thereto.

Light emitted by the first wavelength shifter 340c may have a full width at half maximum (FMHM) of about 45 nm or less, about 40 nm or less, or about 30 nm or less, and thus, the purity of colors displayed by the display device 1 and the color reproducibility of the display device 1 can be further improved. Also, the first wavelength shifter 340c can emit light in various directions regardless of the incidence direction of the light. The side visibility of the second color displayed in the second second-transmitting area TA_2 can be improved.

Some of the emitted light LE provided by the second light-emitting element may not be converted into green light by the first wavelength shifter 340c, but may be emitted through the second light-transmitting member 340. Components of the emitted light LE that are not wavelength-converted by the second light-transmitting member 340, but are incident upon the second filtering pattern area 320_2a of the second color filter 320_2, may be blocked by the second filtering pattern area 320_2a. On the contrary, green light obtained from the emitted light LE by the second light-transmitting member 340 may be emitted out of the display device 1 through the second filtering pattern area 320_2a. That is, the second emitted light L2, which is emitted out of the display device 1 through the second light-transmitting area TA_2, may be green light.

The third light-transmitting member 350 may be disposed in space defined by the bank members BK. The third light-emitting area ELA_3 and the third light-transmitting area TA_3 may overlap with each other in the third coordinate direction DR3. The third light-transmitting member 350 may be in contact with the second capping layer CPL_2 and the bank members BK.

The third light-transmitting member 350 may be a wavelength-shifting pattern capable of converting or shifting the peak wavelength of incident light into another particular peak wavelength. Specifically, the emitted light LE provided by the second light-emitting element may be blue light and may be converted into red light having a peak wavelength of about 610 nm to about 650 nm after passing through the second light-transmitting member 340 and the second filtering pattern area 320_2a of the second color filter 320_2, and the red light may be emitted out of the display device 1. In other words, the third emitted light L3, which is emitted from the third light-emitting area ELA_3 through the third light-transmitting area TA_3, may be red light.

The third light-transmitting member 350 may include a third base resin 350a, a third light scatterer 350b, which is dispersed in the third base resin 350a, and a second wavelength shifter 350c, which is also dispersed in the third base resin 350a. The third base resin 350a may be substantially the same as, or similar to, the first base resin 330a of the first light-transmitting member 330, and thus, a detailed description thereof will be omitted. The third light scatterer 350b may be substantially the same as, or similar to, the first light scatterer 330b of the first light-transmitting member 330, and thus, a detailed description thereof will be omitted. The second wavelength shifter 350c may be substantially the same as, or similar to, the first wavelength shifter 340c of the second light-transmitting member 340, and thus, a detailed description thereof will be omitted.

Some of emitted light LE provided by the third light-emitting element may not be converted into red light by the second wavelength shifter 350c, but may be emitted through the third light-transmitting member 350. Components of the emitted light LE that are not wavelength-converted by the third light-transmitting member 350, but are incident upon the third filtering pattern area 320_3a of the third color filter 320_3, may be blocked by the third filtering pattern area 320_3a. On the contrary, red light obtained from the emitted light LE by the third light-transmitting member 350 may be emitted out of the display device 1 through the third filtering pattern area 320_3a. That is, the third emitted light L3, which is emitted out of the display device 1 through the third light-transmitting area TA_3, may be red light.

The third capping layer CPL_3 may be disposed on the bank members BK and the first, second, and third light-transmitting members 330, 340, and 350 and may prevent external impurities such as moisture or the air from infiltrating into the first, second, and third light-transmitting members 330, 340, and 350 to damage or contaminate the first, second, and third light-transmitting members 330, 340, and 350. The third capping layer CPL_3 may cover the first, second, and third light-transmitting members 330, 340, and 350.

The third capping layer CPL_3 may be formed of an inorganic material. In some embodiments, the third capping layer CPL_3 may be formed of the same material as the second capping layer CPL_2 and may include at least one selected from among the above-described exemplary materials that may be included in the second capping layer CPL_2, but the disclosure is not limited thereto.

The filler part 500 may be interposed between the light-emitting part 100 and the light-transmitting part 300 to fill the gap between the light-emitting part 100 and the light-transmitting part 300. Specifically, in some embodiments, the filler part 500 may be in direct contact with the upper inorganic layer TFEc of the TFE layer and the third capping layer CPL_3 of the light-transmitting part 300, but the disclosure is not limited thereto.

In some embodiments, the filler part 500 may be formed of a material having an extinction coefficient of substantially zero. There is a correlation between refractive index and extinction coefficient, and the less the refractive index, the less the extinction coefficient. When the refractive index is 1.7 or less, the extinction coefficient substantially converges on zero. In some embodiments, the filler part 500 may be formed of a material having a refractive index of 1.7 or less, and as a result, the absorption of light provided by the light-emitting elements, through the filler part 500, can be prevented or minimized. In some embodiments, the filler part 500 may be formed of an organic material having a refractive index of 1.4 to 1.6.

The first, second, and third light-transmitting members 330, 340, and 350 may be formed by ejecting an ink composition from a nozzle NZ, i.e., by using an inkjet printing method. In this case, the bank members BK may function as a guide for stably placing the ink composition at any desired location.

The ink composition may be ejected at a relatively high concentration at an early stage of the application of the ink composition, and as the application of the ink composition progresses, the concentration of the ink composition may decrease, and eventually, the ink composition may be ejected at a uniform concentration. In this case, the concentration of the ink composition may affect the transmittance of the light-transmitting part 300 depending on the location in the display area DA. For example, in a case where the first base resin 330a and the first light scatterer 330b are applied via inkjet printing to form the first light-transmitting member 330, the first light scatterer 330b may be applied at a relatively high concentration at an early phase of the application of the first light scatterer 330b. In this example, if the concentration of the first light scatterer 330b is too high, emitted light LE incident upon the first light-transmitting member 330 may not be able to pass through the first light-transmitting member 330, and as a result, the luminance in a region where the first light scatterer 330b is applied at the early phase of the application of the first light scatterer 330b may be lowered so that smudges may become visible. Accordingly, the luminance in the display area DA needs to be uniformly controlled by controlling the width of the first light-transmitting member 330 to control the amount of the first light scatterer 330b applied.

It will hereinafter be described a structure in which first light-transmitting members 330 have their width controlled.

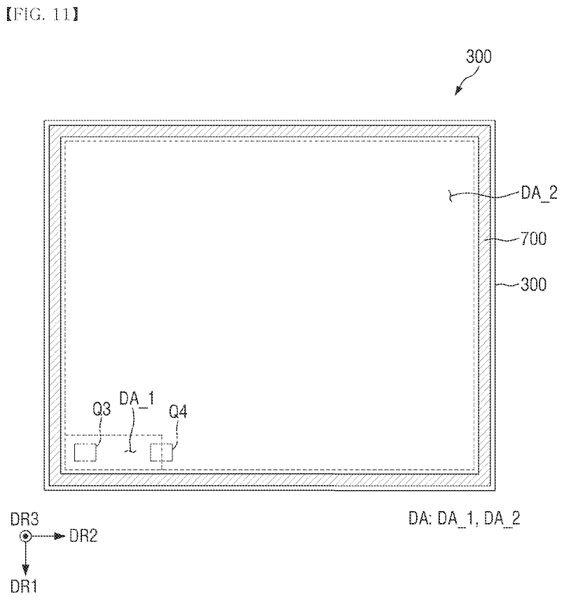

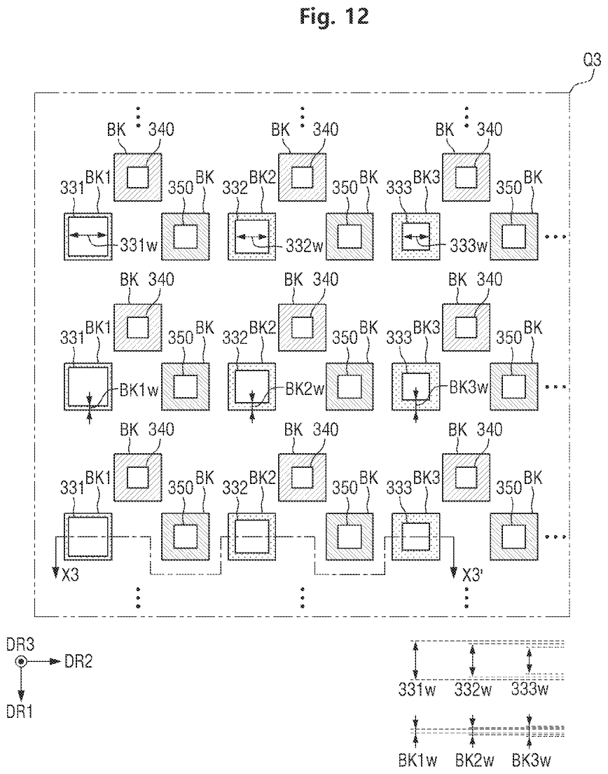

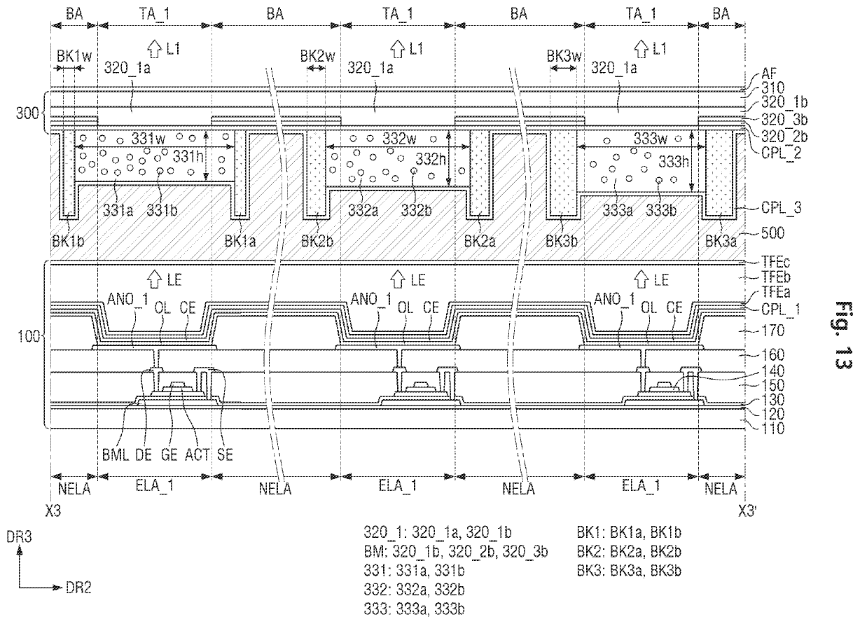

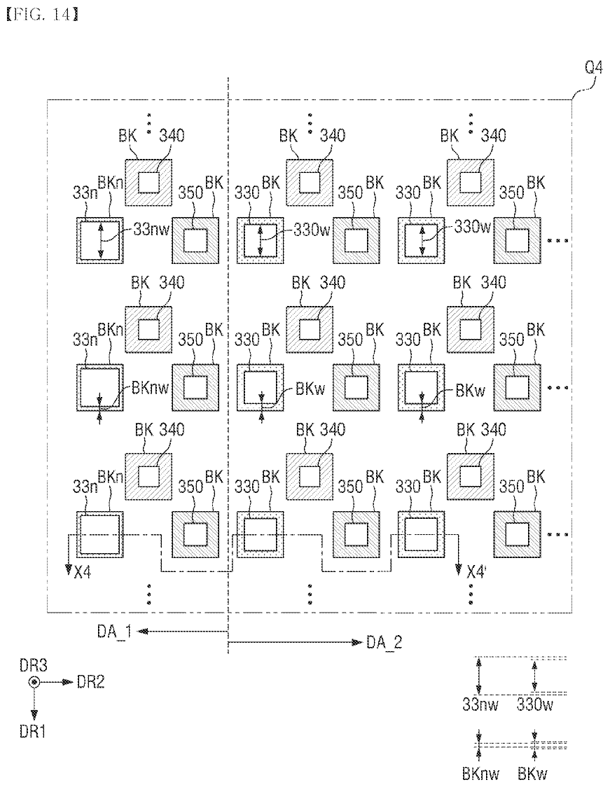

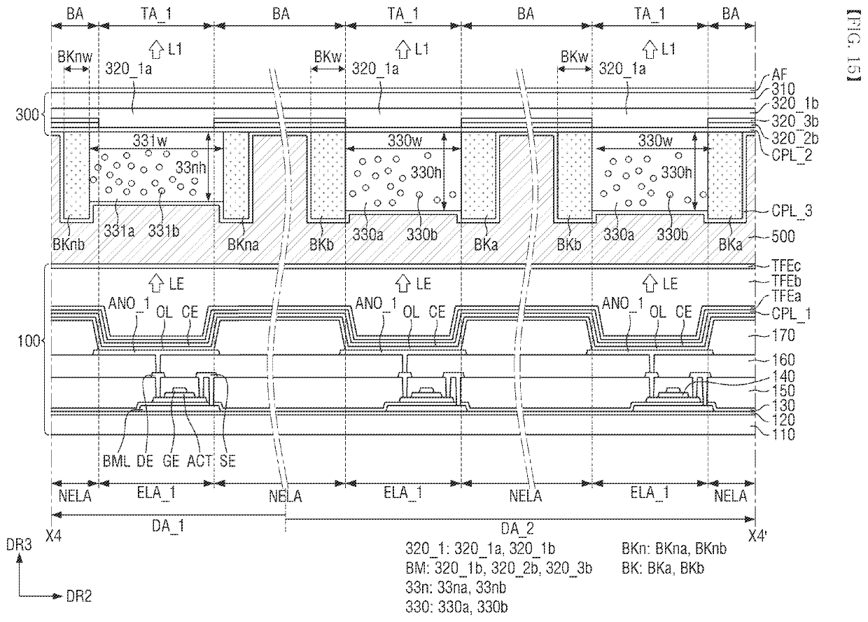

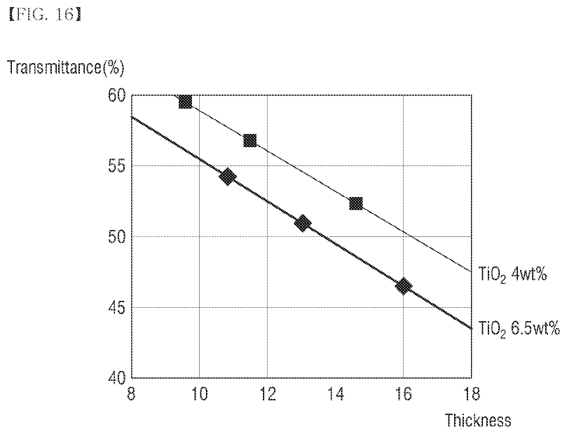

FIG. 11 is a plan view illustrating the layout of first and second areas defined in the display area of the light-transmitting part of the display device of FIG. 1. FIG. 12 is an enlarged plan view of part Q3 of FIG. 11, particularly, light-transmitting members in the first area of FIG. 11. FIG. 13 is a cross-sectional view taken along line X3-X3′ of FIG. 12. FIG. 14 is an enlarged plan view of part Q4 of FIG. 11, particularly, light-transmitting members near the boundary between the first and second areas of FIG. 11. FIG. 15 is a cross-sectional view taken along line X4-X4′ of FIG. 13. FIG. 16 is a graph showing the transmittance of light-transmitting members versus the height of the light-transmitting members or the concentration of light scatterers in the light-transmitting members.

Referring to FIGS. 11 through 16, first and second areas DA_1 and DA_2 may be defined in the display area DA of the display device 1. The first and second areas DA_1 and DA_2 may also be defined in each of the light-transmitting part 300 and the light-emitting part 100.

The first area DA_1 may be an area in which the application of an ink composition by nozzles NZ using an inkjet printing method begins. The first area DA_1 may also be an area in which the width of the bank members BK, the width of first light-transmitting members 330, and the height of the first light-transmitting members 330 vary.

The second area DA_2 may be an area in which the application of the first base resin 330a and the first light scatterer 330b by the nozzles NZ is performed on first light-transmitting members 330 without variation in concentration. The second area DA_2 may also be an area in which the height of the bank members BK, the width of the first light-transmitting members 330, and the height of the first light-transmitting members 330 are uniform. The second area DA_2 may be disposed around the first area DA_1 and may account for most of the display area DA. The area in which the first light-transmitting members 330, second light-transmitting members 340, and third light-transmitting members 350 of FIG. 6 are disposed may correspond to the second area DA_2.

In some embodiments, the first area DA_1 may be disposed on a first or second side, in the first coordinate direction DR1, of the display area DA, but the disclosure is not limited thereto. For convenience, the first area DA_1 will hereinafter be described as being disposed on the first or second side, separated in the first coordinate direction DR1, of the display area DA.

The first area DA_1 may adjoin the second area DA_2 not only in a row direction, i.e., in the second coordinate direction DR2, but also in a column direction, i.e., in the first coordinate direction DR1. In some embodiments, the width and height of the light-transmitting members in the first area DA_1 may vary in the second coordinate direction DR2, but not in the first coordinate direction DR1, but the disclosure is not limited thereto. For convenience, the width and heights of the light-transmitting members in the first area DA_1 will hereinafter be described as varying in the second coordinate direction DR2, but not in the first coordinate direction DR1.

FIG. 12 depicts the region Q3 shown in FIG. 11, which is entirely located in the first display area DA_1. Referring to FIGS. 12 and 13, in the first area DA_1, (1_1)-th, (1_2)-th, and (1_3)-th light-transmitting members 331, 332, and 333 may be sequentially arranged in the same row, i.e., in an imaginary row extending in the second coordinate direction DR2. As used herein, the convention (1_2) indicates row 1, column 2 in a layout such as what is depicted in FIG. 12, wherein each “unit” that is arranged in rows and columns includes 33n, 340, and 350 (with n being a non-zero positive integer because 330 is in the second display area DA_2). The units, which may be generally depicted as Q1 in FIG. 3, are spaced apart from one another. The (1_1)-th light-transmitting members 331, (1_2)-th light-transmitting members 332, and (1_3)-th light-transmitting members 333 may be formed of the same material as first light-transmitting members 330 in the second area DA_2 and may be substantially the same as the first light-transmitting members 330 in the second area DA_2 except for their widths and heights in the second and third coordinate directions DR2 and DR3, respectively. In other words, in the display area DA_1, the width of first light-transmitting areas TA_1 and first light-emitting areas ELA_1 may be constant, and only the width of the first light-transmitting members 330 may vary in the second coordinate direction DR2. Thus, the (1_1)-th light-transmitting members 331, the (1_2)-th light-transmitting members 332, and the (1_3)-th light-transmitting members 333, like the first light-transmitting members 330 in the second area DA_2, may overlap with the first light-emitting areas ELA_1 of the light-emitting part 100 and the first light-transmitting areas TA_1 of the light-transmitting part 300 in the third coordinate direction DR3.

In some embodiments, second light-transmitting members 340 and third light-transmitting members 350 may be arranged not only in the second area DA_2, but also in the first area DA_1, and the width and the height of the second light-transmitting members 340 and the third light-transmitting members 350 may remain constant. However, the disclosure is not limited to this.

Each of the (1_1)-th light-transmitting members 331 may include a (1_1)-th base resin 331a and a (1_1)-th light scatterer 331b that is dispersed in the (1_1)-th base resin 331a, each of the (1_2)-th light-transmitting members 332 may include a (1_2)-th base resin 332a and a (1_2)-th light scatterer 332b, which is dispersed in the (1_2)-th base resin 332a, and each of the (1_3)-th light-transmitting members 333 may include a (1_3)-th base resin 333a and a (1_3)-th light scatterer 333b, which is dispersed in the (1_3)-th base resin 333a. The (1_1)-th, (1_2)-th, and (1_3)-th base resins 331a, 332a, and 333a are substantially the same as, or similar to, the first baes resin 330a of the first light-transmitting member 330 of FIG. 6, and thus, detailed descriptions thereof will be omitted. The (1_1)-th, (1_2)-th, and (1_3)-th light scatterers 331b, 332b, and 333b are substantially the same as, or similar to, the first light scatterer 330b of the first light-transmitting member 330 of FIG. 6, and thus, detailed descriptions thereof will be omitted.

In some embodiments, the (1_1)-th light-transmitting members 331, the (1_2)-th light-transmitting members 332, and the (1_3)-th light-transmitting members 333 may have a square shape in plan view, but the disclosure is not limited thereto. In some embodiments, the second light-transmitting members 340 and the third light-transmitting members 350 may have a square shape in plan view and may have the same size, but the disclosure is not limited thereto.

In some embodiments, the size of the (1_1)-th light-transmitting members 331, the (1_2)-th light-transmitting members 332, and the (1_3)-th light-transmitting members 333 may be greater than the size of the second light-transmitting members 340 or the size of the third light-emitting members 350, but the disclosure is not limited thereto. For convenience, the second light-transmitting members 340 and the third light-transmitting members 350 will hereinafter be described as having a square shape in a plan view and having the same size, and the (1_1)-th light-transmitting members 331, the (1_2)-th light-transmitting members 332, and the (1_3)-th light-transmitting members 333 will hereinafter be described as having a square shape in plan view and having a larger size than the second light-transmitting members 340 and the third light-transmitting members 350.

A width 331w of the (1_1)-th light-transmitting members 331 may be greater than the width of the first light-emitting areas ELA_1 and the width of the first light-transmitting areas TA_1. Accordingly, parts of the (1_1)-th light-transmitting members 331 may overlap with the pixel-defining film 170 of the light-emitting part 100 and the light-blocking areas BA of the light-transmitting part 300 in the third coordinate direction DR3.

A width 332w of the (1_2)-th light-transmitting members 332 may be greater than the width of the first light-emitting areas ELA_1 and the width of the first light-transmitting areas TA_1. Accordingly, parts of the (1_2)-th light-transmitting members 332 may overlap with the pixel-defining film 170 of the light-emitting part 100 and the light-blocking areas BA of the light-transmitting part 300 in the third coordinate direction DR3.

A width 333w of the (1_3)-th light-transmitting members 333 may be greater than the width of the first light-emitting areas ELA_1 and the width of the first light-transmitting areas TA_1. Accordingly, parts of the (1_3)-th light-transmitting members 333 may overlap with the pixel-defining film 170 of the light-emitting part 100 and the light-blocking areas BA of the light-transmitting part 300 in the third coordinate direction DR3.

In some embodiments, the (1_1)-th light-transmitting members 331, the (1_2)-th light-transmitting members 332, and the (1_3)-th light-transmitting members 333 may have a square shape in plan view, but the disclosure is not limited thereto. In some embodiments, the second light-transmitting members 340 and the third light-transmitting members 350 may have a square shape in plan view and have substantially the same size, but the disclosure is not limited thereto.

The width of light-transmitting members in the first area DA_1 may decrease along the second coordinate direction DR2, and the height of the light-transmitting members in the first area DA_1 may increase along the second coordinate direction DR2.

Specifically, the width 331w of the (1_1)-th light-transmitting members 331 may be greater than the width 332w of the (1_2)-th light-transmitting members 332 and the width 333w of the (1_3)-th light-transmitting members 333, and the width 332w of the (1_2)-th light-transmitting members 332 may be greater than the width 333w of the (1_3)-th light-transmitting members 333. Also, a height 331h of the (1_1)-th light-transmitting members 331 may be less than a height 332h of the (1_2)-th light-transmitting members 332 and a height 333h of the (1_3)-th light-transmitting members 333, and the height 332h of the (1_2)-th light-transmitting members 332 may be less than the height 333h of the (1_3)-th light-transmitting members 333.

The concentration of a light scatterer dispersed in each of the light-transmitting members in the first area DA_1 may change along the second coordinate direction DR2.

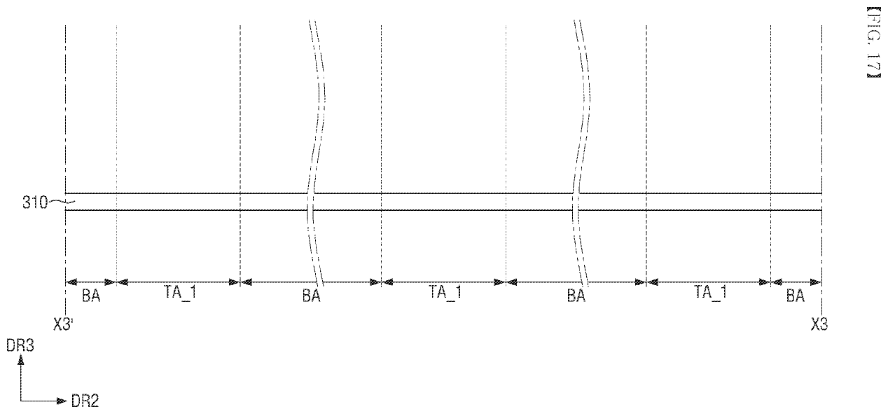

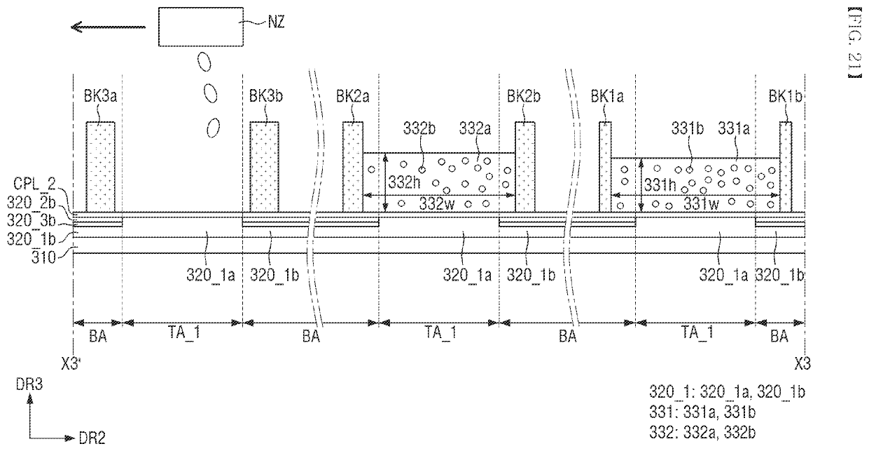

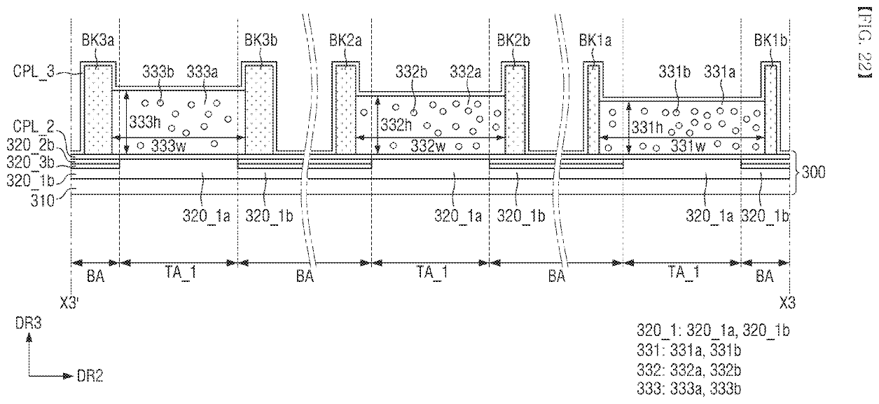

In one embodiment, the concentration of (1_1)-th light scatterers 331b in the (1_1)-th light-transmitting members 331 may be higher than the concentration of (1_2)-th light scatterers 332b in the (1_2)-th light-transmitting members 332 and the concentration of (1_3)-th light scatterers 333b in the (1_3)-th light-transmitting members 333, and the concentration of the (1_2)-th light scatterers 332b in the (1_2)-th light-transmitting members 332 may be higher than the concentration of the (1_3)-th light scatterers 333b in the (1_3)-th light-transmitting members 333. This is because during the formation of the (1_1)-th light-transmitting members 331, the (1_2)-th light-transmitting members 332, and the (1_3)-th light-transmitting members 333 through inkjet printing using the nozzles NZ (see FIGS. 17 through 22), an ink composition is ejected from the nozzles NZ at a relatively high concentration at an early stage of the application of the ink composition. Here, the “concentration” of an ink composition may refer to the concentration of light scatterers per volume of composition that forms the light transmitting members 331/332/333.

Referring to FIG. 16, the y axis represents the light transmittance of light-transmitting members, and the x axis represents the height of light-transmitting members. The higher the concentration of light scatterers, the lower the light transmittance of light-transmitting members, and the higher the light-transmitting members, the lower the light-transmittance of the light-transmitting members. Thus, in a case where light scatterers are ejected at a relatively high concentration at an early phase of the application of the light scatterers, sufficient light transmittance can be secured only if light-transmitting members are thin. In the embodiment of FIGS. 11 through 15, as the concentration of light scatterers dispersed in the light-transmitting members in the first area DA_1 decreases along the second coordinate direction DR2 and the height of the light-transmitting members increases along the second coordinate direction DR2, the light transmittance of the light-transmitting members may become uniform regardless of the location in the display area DA. In other words, the number of particles of the light scatterers per unit height of the light-transmitting members may be substantially uniform along the second coordinate direction DR2, and as a result, the light transmittance of the light-transmitting members may become uniform regardless of the location in the display area DA.

Empirical data reveal the concentration of light scatterers and the width and the height of light-transmitting members that can provide a uniform light transmittance throughout the entire display area of a display device, as shown in Table 1 below.

TABLE 1

| Concentration of TiO₂ (%) | 8.6% | 7.7% | 7.3% | 7.0% | 6.5% | |
|---|---|---|---|---|---|---|
| Height of Light-Transmitting | 6.9 μm | 7.8 μm | 8.2 μm | 8.5 μm | 9 | μm |
| Member (μm) | | | | | | |
| Width of Light-Transmitting | 131.9 μm | 124.1 μm | 121.0 μm | 118.8 μm | 115.5 | μm |
| Member (μm) | | | | | | |

| | |
|---|---|
| Transmittance (%) | 53% |

The dispersion for each numerical value listed in Table 1 above may be about 5%. Referring to Table 1, the higher the concentration of light scatterers ejected, the less the height of light-transmitting members, and the greater the width of the light-transmitting members are to achieve the same level of transmittance.

The number of particles of the (1_1)-th light scatterers 331b per unit height of the (1_1)-th light-transmitting members 331 may be substantially the same as the number of particles of the (1_2)-th light scatterers 332b per unit height of the (1_2)-th light-transmitting members 332 and the number of particles of the (1_3)-th light scatterers 333b per unit height of the (1_3)-th light-transmitting members 333. Accordingly, the transmittances of the (1_1)-th light-transmitting members 331, the (1_2)-th light-transmitting members 332, and the (1_3)-th light-transmitting members 333 may become substantially the same, and the luminance of the emitted light LE from the first light-emitting areas ELA_1 may become substantially the same regardless of whether the emitted light LE from the first light-emitting areas ELA_1 passes through the (1_1)-th light-transmitting members 331, the (1_2)-th light-transmitting members 332, or the (1_3)-th light-transmitting members 333.

In other words, emitted light LE from first light-emitting areas ELA_1 overlapping with the (1_1)-th light-transmitting members 331 in the third coordinate direction DR3 may be emitted out of the display device 1 through the (1_1)-th light-transmitting members 331 as first emitted light L1, emitted light LE from first light-emitting areas ELA_1 overlapping with the (1_2)-th light-transmitting members 332 in the third coordinate direction DR3 may be emitted out of the display device 1 through the (1_2)-th light-transmitting members 331 as first emitted light L1, emitted light LE from first light-emitting areas ELA_1 overlapping with the (1_3)-th light-transmitting members 333 in the third coordinate direction DR3 may be emitted out of the display device 1 through the (1_3)-th light-transmitting members 331 as first emitted light L1, and the luminance of the first emitted light L1 passing through the (1_1)-th light-transmitting members 331, the luminance of the first emitted light L1 passing through the (1_2)-th light-transmitting members 332, and the luminance of the first emitted light L1 passing through the (1_3)-th light-transmitting members 333 may be substantially the same. Thus, smudges can be prevented from being generated in the display area DA.

The bank members BK may be disposed to surround the edges of each light-transmitting member. In some embodiments, the bank members BK may be disposed to be spaced apart from one another and thus to correspond to the light-transmitting members, but the disclosure is not limited thereto. Alternatively, the bank member BK may be connected to one another. For convenience, the bank members BK will hereinafter be described as being spaced apart from one another.

Referring to FIG. 12, the bank members BK may include, in the first area DA_1, first bank members BK1 that surround the (1_1)-th light-transmitting members 331, second bank members BK2 that surround the (1_2)-th light-transmitting members 332, and third bank members BK3 that surround the (1_3)-th light-transmitting members 333. In the first area DA_1, the first bank members BK1, the second bank members BK2, and the third bank members BK3 may be spaced apart from one another in the second coordinate direction DR2, as illustrated in FIG. 12. The first bank members BK1, the second bank members BK2, and the third bank members BK3 may be substantially the same as bank members BK in the second area DA_2 except for their exact dimensions.

The first bank members BK1 may surround the edges of each of the (1_1)-th light-transmitting members 331. As a result, the width of the (1_1)-th light-transmitting members 331 may be the same as the distance between a pair of opposite sidewalls of each of the first bank members BK1. Specifically, referring to FIG. 13, each of the first bank members BK1 may have first and second sidewalls BK1a and BK1b, which are on first and second sides of the corresponding first bank member BK1, and the distance, in the second coordinate direction DR2, between the first and second sidewalls BK1a and BK1b may be substantially the same as the width 331w of the (1_1)-th light-transmitting members 331. The first bank members BK1 may surround the (1_1)-th light-transmitting member 331 to form a border around the (1_1)-th light-transmitting member 331 having a uniform thickness that is equivalent to width BK1w. Accordingly, the distance, in the second coordinate direction DR2, between the first and second sidewalls BK1a and BK1b, i.e., the border thickness (the width BK1w), may be substantially uniform. The first bank members BK1 may not overlap with the first light-emitting areas ELA_1 of the light-emitting part 100 and the first light-transmitting areas TA_1 of the light-transmitting part 300 in the third coordinate direction DR3.

The second bank members BK2 may surround the edges of each of the (1_2)-th light-transmitting members 332. As a result, the width of the (1_2)-th light-transmitting members 332 may be the same as the distance between a pair of opposite sidewalls of each of the second bank members BK2. Specifically, referring to FIG. 13, each of the second bank members BK2 may have first and second sidewalls BK2a and BK2b, which are on first and second sides of the corresponding second bank member BK2, and the distance, in the second coordinate direction DR2, between the first and second sidewalls BK2a and BK2b may be substantially the same as the width 332w of the (1_2)-th light-transmitting members 332. The second bank members BK2 may surround the (1_2)-th light-transmitting member 332 to form a border around the (1_2)-th light-transmitting member 332 having a uniform thickness that is equivalent to width BK2w. Accordingly, the distance, in the second coordinate direction DR2, between the first and second sidewalls BK2a and BK2b, i.e., the border thickness (width BK2w), may be substantially uniform. The second bank members BK2 may not overlap with the first light-emitting areas ELA_1 of the light-emitting part 100 and the first light-transmitting areas TA_1 of the light-transmitting part 300 in the third coordinate direction DR3.

The third bank members BK3 may surround the edges of each of the (1_3)-th light-transmitting members 333. As a result, the width of the (1_3)-th light-transmitting members 333 may be the same as the distance between a pair of opposite sidewalls of each of the third bank members BK3. Specifically, referring to FIG. 13, each of the third bank members BK3 may have first and second sidewalls BK3a and BK3b, which are on first and second sides of the corresponding third bank member BK3, and the distance, in the second coordinate direction DR2, between the first and second sidewalls BK3a and BK3b may be substantially the same as the width 333w of the (1_3)-th light-transmitting members 333. The third bank members BK3 may surround the (1_3)-th light-transmitting member 333 to form a border around the (1_3)-th light-transmitting member 333 having a uniform thickness that is equivalent to width BK3w. Accordingly, the distance, in the second coordinate direction DR2, between the first and second sidewalls BK3a and BK3b, i.e., the border thickness (the width BK3w), may be substantially uniform. The third bank members BK3 may not overlap with the first light-emitting areas ELA_1 of the light-emitting part 100 and the first light-transmitting areas TA_1 of the light-transmitting part 300 in the third coordinate direction DR3.

As already mentioned above, as the width of the light-transmitting members in the first area DA_1 decreases along the second coordinate direction DR2, the border thickness of the bank members BK may increase along the second coordinate direction DR2 (see FIG. 13). Specifically, as the width, in the second coordinate direction DR2, of the light-transmitting members in the first area DA_1 increases going from width 331w to 332w to 333w, the width BK1w of the first bank members BK1 may be less than the width BK2w of the second bank members BK2 and the width BK3w of the third bank members BK3, and the width BK2w of the second bank members BK2 may be less than the width BK3w of the third bank members BK3.

FIG. 14 depicts the area Q4 of FIG. 11, which is partially in the first display area DA_1 and partially in the second display area DA_2. Referring to FIGS. 14 and 15, the width of the first light-transmitting members 330 in the second area DA_2, the height of the first light-transmitting members 330 in the second area DA_2, and a width BKw of bank members BK surrounding the first light-transmitting members 330 in the second area DA_2 may be substantially uniform along the second coordinate direction DR2. The second area DA_2 may be an area in which an ink composition is ejected from the nozzles at a uniform concentration.

The (1_n)-th light-transmitting members 33n may be disposed in an end part of the first area DA_1, i.e., in an edge part of the first area DA_1 near the second area DA_2. First light-transmitting members 330 may be repeatedly arranged in the second area DA_2 along the second coordinate direction DR2. The (1_n)-th light-transmitting members 33n (wherein n=a non-negative integer) may be formed of the same material as the first light-transmitting members 330 in the second area DA_2, but may have its width in the second coordinate direction DR2 or its height in the third coordinate direction DR3 vary.

Each of the (1_n)-th light-transmitting members 33n may include a (1_n)-th base resin 33na and a (1_n)-th light scatterer 330nb, which is dispersed in the (1_n)-th base resin 33na. The (1_n)-th base resin 330a may be substantially the same as, or similar to, the first base resin 330a of the first light-transmitting member 330 of FIG. 6, and thus, a detailed description thereof will be omitted. The (1_n)-th light scatterer 33nb may be substantially the same as, or similar to, the first light scatterer 330b of the first light-transmitting member 330 of FIG. 6, and thus, a detailed description thereof will be omitted.

Referring to FIG. 11, the (1_n)-th light-transmitting members 33n are disposed in one end of the first area DA_1 that is closest to the second area DA_2. Due to the relative widths having the relation 331w>332w>333w moving in the second coordinate direction DR2, the width 33nw of the (1_n)-th light-transmitting members 33n may be less than the width 331w of the (1_1)-th light-transmitting members 331, the width 332w of the (1_2)-th light-transmitting members 332, and the width 333w of the (1_3)-th light-transmitting members 333. As for the height, due to the height increasing along the second coordinate direction DR2, height 33nb of the (1_n)-th light-transmitting members 33n may be greater than a height 331h of the (1_1)-th light-transmitting members 331, a height 332h of the (1_2)-th light-transmitting members 332, and a height 333h of the (1_3)-th light-transmitting members 333. Also, the concentration of (1_n)-th light scatterer 33nb in the (1_n)-th light-transmitting members 33n may be lower than the concentration of the (1_1)-th light scatterer 331b in the (1_1)-th light-transmitting members 331, the concentration of the (1_2)-th light scatterer 332b in the (1_2)-th light-transmitting members 332, and the concentration of the (1_3)-th light scatterer 333b in the (1_3)-th light-transmitting members 333. Also, the number of particles of the (1_n)-th light scatterers 33nb per unit height of the (1_n)-th light-transmitting members 33n may be substantially the same as the number of particles of the (1_1)-th light scatterers 331b per unit height of the (1_1)-th light-transmitting members 331, the number of particles of the (1_2)-th light scatterers 332b per unit height of the (1_2)-th light-transmitting members 332, and the number of particles of the (1_3)-th light scatterers 333b per unit height of the (1_3)-th light-transmitting members 333.

The width 33nw of the (1_n)-th light-transmitting members 33n at an end of the first area DA_1 may be greater than the width 330w of the first light-transmitting members 330 in the second area DA_2, and the height 33nb of the (1_n)-th light-transmitting members 33n may be less than a height 330h of the first light-transmitting members 330.

The concentration of the (1_n)-th light scatterers 33nb in the (1_n)-th light-transmitting members 33n may be greater than the concentration of the first light scatterers 330b in the first light-transmitting members 330. However, the number of particles of the (1_n)-th light scatterers 33nb per unit height of the (1_n)-th light-transmitting members 33n may be substantially the same as the number of particles of the first light scatterers 330b per unit height of the first light-transmitting members 330. Accordingly, the luminance of light emitted from the first area DA_1 may be substantially the same as the luminance of light emitted from the second area DA_2.

Referring to FIG. 12 and FIG. 13, n-th bank members BKn may be disposed to surround the (1_n)-th light-transmitting members 33n. As a result, the width of the (1_n)-th light-transmitting members 33n may be the same as the distance between a pair of opposite sidewalls of each of the n-th bank members BKn. Specifically, each of the n-th bank members BKn may have first and second sidewalls BKna and BKnb, which are on first and second sides, in the second coordinate direction DR2, of the corresponding n-th bank member BKn, and the distance, in the second coordinate direction DR2, between the first and second sidewalls BKna and BKnb may be substantially the same as the width 33nw, in the second coordinate direction DR2, of the (1_n)-th light-transmitting members 33n. The n-th bank members BKn may surround the (1_n)-th light-transmitting member 33n, having a uniform width BKnw. Accordingly, the distance, in the second coordinate direction DR2, between the first and second sidewalls BKna and BKnb, i.e., the width BKnw, may be substantially uniform.

As already mentioned above, the width of the bank members BK in the first area DA_1 increases along the second coordinate direction DR2. Hence, the width BKnw of the n-th bank members BKn may be greater than the width BK1w of the first bank members BK1, the width BK2w of the second bank members BK2, and the width BK3w of the third bank members BK3. The border thickness, which is equivalent to the width BKnw, of the n-th bank members BKn may be less than the border thickness (width BKw) of the bank members BK in the second area DA_2.

In some embodiments, in the second area DA_2, the width of the first light-transmitting members 330, the width of the second light-transmitting members 340, and the width of the third light-transmitting members 350 may be substantially the same, but the disclosure is not limited thereto.

The display device 1 can emit light at the same luminance from both the first and second areas DA_1 and DA_2 thereof and can prevent smudges.

A method of fabricating bank members and light-transmitting members in the first area of the light-transmitting part of the display device of FIG. 1 will hereinafter be described with reference to FIGS. 17 through 22.

FIGS. 17 through 22 are cross-sectional views illustrating how to fabricate the light-transmitting part of the display device of FIG. 1.

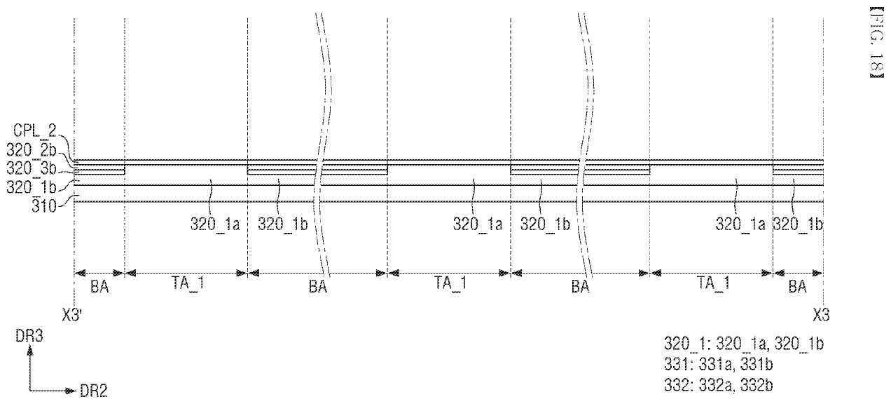

Referring to FIGS. 17 and 18, a second substrate 310 may be prepared, color filter members 320 may be arranged on the second substrate 310, and a second capping layer CPL_2 may be formed on the color filter members 320. The fabrication of the light-transmitting part 300 may be performed with the second substrate 310 turned upside down by 180 degrees. The arrangement of the color filter members 320 on the second substrate 310 may be a process of sequentially arranging first, second, and third color filters 320_1, 320_2, and 320_3 on the second substrate 310.

The arrangement of the color filter members 320 and the formation of the second capping layer CPL_2 are already well known in the art to which the disclosure pertains, and thus, detailed descriptions thereof will be omitted.

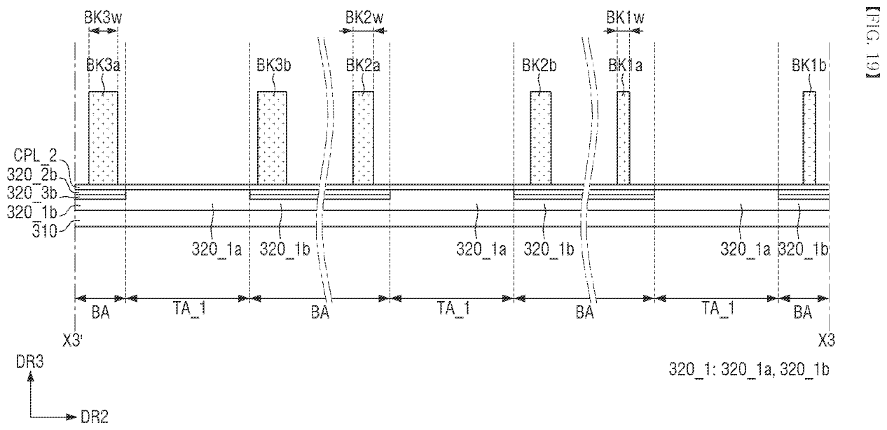

Referring to FIG. 19, first, second, and third bank members BK1, BK2, and BK3 may be arranged on the second capping layer CPL_2. The first, second, and third bank members BK1, BK2, and BK3 may be arranged side-by-side along the second coordinate direction DR2. The first, second, and third bank members BK1, BK2, and BK3 may be formed by applying a photosensitive organic material and exposing and developing the photosensitive organic material to pattern the photosensitive organic material.

As already mentioned above, the distance between first and second sidewalls BK1a and BK1b of the first bank member BK1 may be greater than the distance between first and second sidewalls BK2a and BK2b of the second bank member BK2, and the distance between the first and second sidewalls BK2a and BK2b of the second bank member BK2 may be greater than the distance between first and second sidewalls BK3a and BK3b of the third bank member BK3.

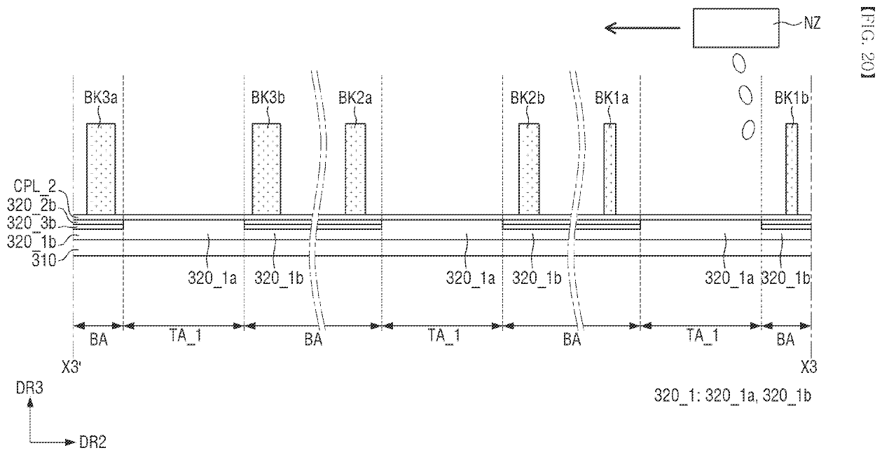

Referring to FIGS. 20 through 22, a (1_1)-th light-transmitting member 331 may be formed in the gap between the first and second sidewalls BK1a and BK1b of the first bank member BK1, a (1_2)-th light-transmitting member 332 may be formed in the gap between the first and second sidewalls BK2a and BK2b of the second bank member BK2, a (1_3)-th light-transmitting member 333 may be formed in the gap between the first and second sidewalls BK3a and BK3b of the second bank member BK3, and a third capping layer CPL_3 may be formed on the first, second, and third bank members BK1, BK2, and BK3 and the (1_1)-th, (1_2)-th, and (1_3)-th light-transmitting members 331, 332, and 333. The formation of the (1_1)-th, (1_2)-th, and (1_3)-th light-transmitting members 331, 332, and 333 may be performed by depositing an ink composition through inkjet printing using the nozzles NZ.

The ink composition ejected through the nozzles NZ may be the mixture of a base resin and a light scatterer. The ink composition that is deposited into the gap between the first and second sidewalls BK1a and BK1b of the first bank member BK1 where the (1_1)-th light-transmitting member 331 is formed may include a (1_1)-th base resin 331a and a (1_1)-th light scatterer 331b, the ink composition ejected into the gap between the first and second sidewalls BK2a and BK2b of the second bank member BK2 where the (1_2)-th light-transmitting member 332 is formed may include a (1_2)-th base resin 332a and a (1_2)-th light scatterer 332b, and the ink composition ejected into the gap between the first and second sidewalls BK3a and BK3b of the third bank member BK3 where the (1_3)-th light-transmitting member 333 is formed may include a (1_3)-th base resin 333a and a (1_3)-th light scatterer 333b.

In some embodiments, the nozzles NZ may operate row by row, by dividing the display area DA into “rows.” Specifically, referring to FIG. 11, the nozzles NZ may start ejecting the ink composition from one side of the display area DA to the other side in the first direction DR1, and also from one side to the other side in the second coordinate direction DR2 while ejecting the ink composition. In one embodiment, the nozzles NZ may move in the first coordinate direction DR1 by a predetermined distance, and may then eject the ink composition in the second coordinate direction DR2. In other words, the display area DA may be divided into multiple rows, and the nozzles NZ may be driven to apply the ink composition to a first row and to move to a second row and apply the ink composition to the second row upon the completion of the application of the ink composition to the first row. The first area DA_1 may be an area in the first row where the application of the ink composition by the nozzles NZ begins.

The concentration of each light scatterer in the ink composition ejected from the nozzles NZ may be at its maximum at the beginning of the ejection of the ink composition. Then, as the nozzles NZ move in the second coordinate direction DR2, the concentration of each light scatterer in the ink composition ejected from the nozzles NZ may decrease and may stabilize once the application of the ink composition proceeds to some extent. Specifically, referring to FIG. 11, the concentration of each light scatterer in the ink composition ejected from the nozzles NZ may decrease while the ink composition is being ejected in the first area DA_1, and may have reached a stable concentration by the time the ejection of the ink composition onto the second area DA_2 begins.

As the distance between the first and second sidewalls BK1a and BK1b of the first bank member BK1 is greater than the distance between the first and second sidewalls BK2a and BK2b of the second bank member BK2, the distance between the first and second sidewalls BK2a and BK2b of the second bank member BK2 is greater than the distance between the first and second sidewalls BK3a and BK3b of the third bank member BK3. The nozzles NZ eject a predetermined amount of base resin onto each of the gaps between the first and second sidewalls BK1a and BK1b of the first bank member BK1, between the first and second sidewalls BK2a and BK2b of the second bank member BK2, and between the first and second sidewalls BK3a and BK3b of the third bank member BK3 while moving. Thus, the heights 331h, 332h, and 333h of the (1_1)-th, (1_2)-th, and (1_3)-th light-transmitting members 331, 332, and 333 may differ from one another. In other words, as already mentioned above, the height of light-transmitting members (331, 332, and 333) may increase in the order of the (1_1)-th, (1_2)-th, and (1_3)-th light-transmitting members 331, 332, and 333.

Accordingly, as the concentration of a light scatterer is highest in the (1_1)-th light-transmitting member 331 and the (1_1)-th light-transmitting member 331 has a smallest height 331h, sufficient light transmittance can be secured, as already mentioned above with reference to FIG. 16, and as high light transmittance can also be secured in the (1_2)-th and (1_3)-th light-transmitting members 332 and 333.

The formation of the third capping layer CPL_3 is already well known to the art to which the disclosure pertains, and thus, a detailed description thereof will be omitted.

Display devices according to other embodiments of the disclosure will hereinafter be described, focusing mainly on the differences with the display device of FIG. 1. Like reference numerals indicate like elements, and redundant descriptions thereof will be omitted.

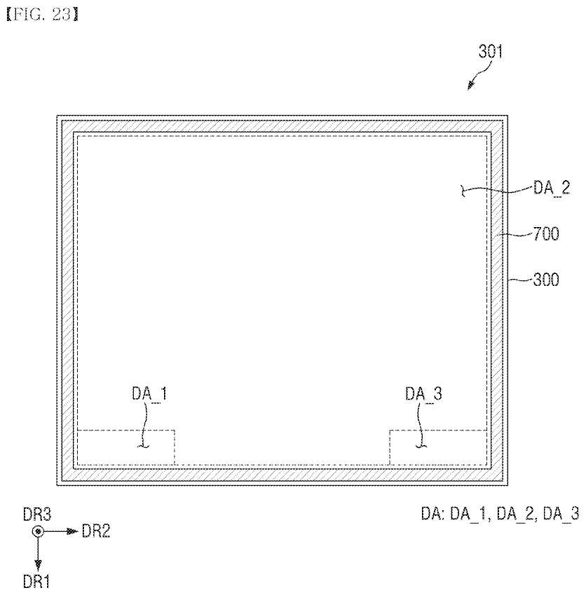

FIG. 23 is a plan view illustrating a light-transmitting part of a display device according to another embodiment of the disclosure.

Referring to FIG. 23, a display device 1_1 may have multiple areas in which the width of light-transmitting members is non-uniform. Specifically, first, second, and third areas DA_1, DA_2, and DA_3 may be defined in a display area DA of the display device 1_1, and the first and third areas DA_1 and DA_3 may be areas in which the width of light-transmitting members is non-uniform, may be arranged in the same row, and may be opposite to each other in a second coordinate direction DR2 with the second area DA_2 interposed therebetween.

Multiple areas in which the width of light-transmitting members is non-uniform may be provided depending on how to deposit an ink composition via nozzles NZ. For example, in a case where the ejection of an ink composition by a plurality of nozzles NZ starts at two opposite ends of the display area DA separated in the second coordinate direction DR2, the concentration of light scatterers in each of the first and third areas DA_1 and DA_3 varies, and the light transmittance of each of the first and third areas DA_1 and DA_3 may be controlled by controlling the width of light-transmitting members in each of the first and third areas DA_1 and DA_3.

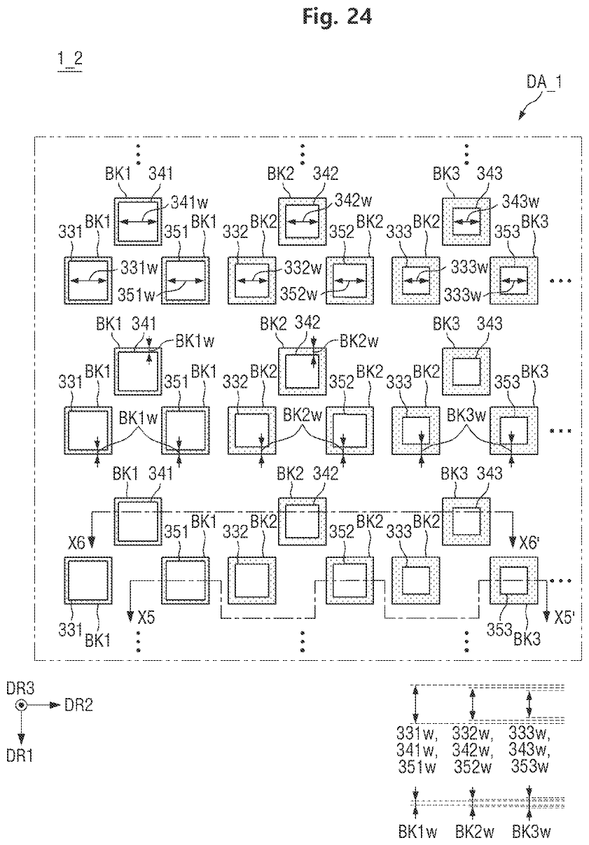

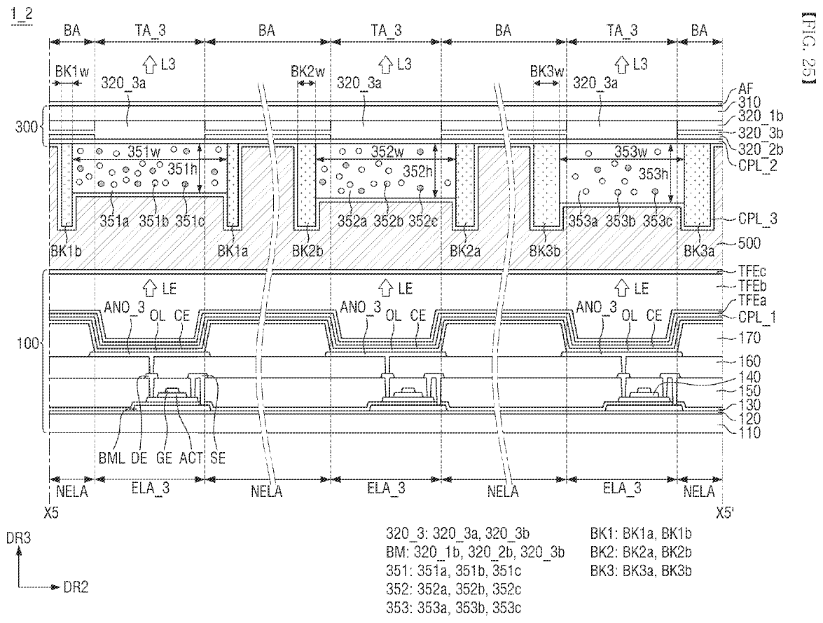

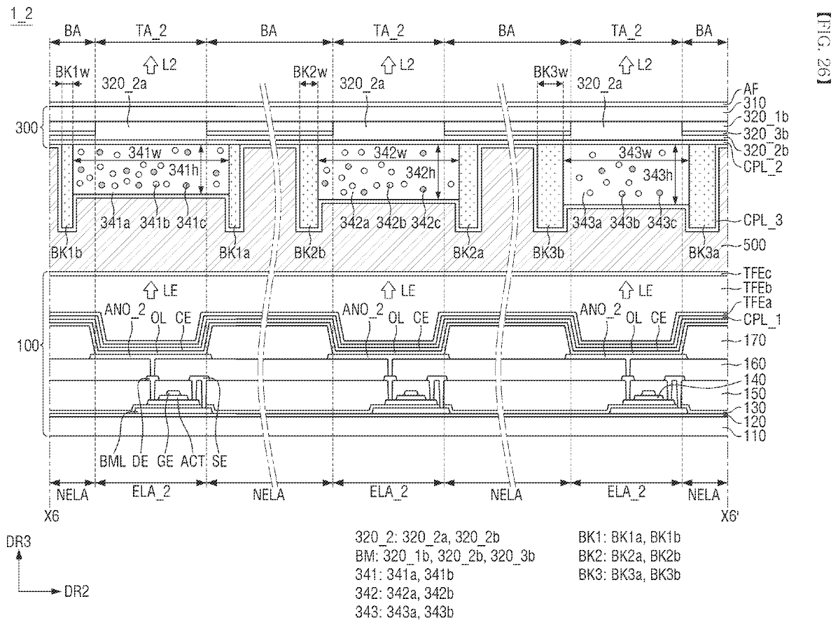

FIG. 24 is a plan view illustrating light-transmitting members in a first area of a light-transmitting part of a display device according to another embodiment of the disclosure. FIG. 25 is a cross-sectional view taken along line X5-X5′ of FIG. 24. FIG. 26 is a cross-sectional view taken along line X6-X6′ of FIG. 24.

Referring to FIGS. 24 through 26, not only the width of first light-transmitting members 330, but also the width of second light-transmitting members 340 and the width of third light-transmitting members 350 may be varied. Specifically, the width of the first light-transmitting members 330, the width of the second light-transmitting members 340, and the width of the third light-transmitting members 350 may decrease along a second coordinate direction DR2 in a first area DA_1 of a display area DA of a display device 1_2.

In the first area DA_1, (1_1)-th, (1_2)-th, and (1_3)-th light-transmitting members 331, 332, and 333 may be sequentially arranged in each row along the second coordinate direction DR2 to be spaced apart from one another. The (1_1)-th light-transmitting members 331, (1_2)-th light-transmitting members 332, and (1_3)-th light-transmitting members 333, which are disposed in the first area DA_1, may be formed of the same material as first light-transmitting members 330, which are disposed in a second area DA_2 of the display area DA_ of the display device 1_2, but may have their widths or heights varied. The (1_1)-th light-transmitting members 331, the (1_2)-th light-transmitting members 332, and the (1_3)-th light-transmitting members 333 are as already described above with reference to FIGS. 12 and 13, and thus, detailed descriptions thereof will be omitted.

In the first area DA_1, (2_1)-th, (2_2)-th, and (2_3)-th light-transmitting members 341, 342, and 343 may be sequentially arranged in each row along the second coordinate direction DR2 to be spaced apart from one another. (2_1)-th light-transmitting members 341, (2_2)-th light-transmitting members 342, and (2_3)-th light-transmitting members 343, which are disposed in the first area DA_1, may be formed of the same material as second light-transmitting members 340, which are disposed in the second area DA_2, but may have their widths in the second coordinate direction DR2 or heights varied.

Each of the (2_1)-th light-transmitting members 341 may include a (2_1)-th base resin 341a, a (2_1)-th light scatterer 341b that is dispersed in the (2_1)-th base resin 341a, and a (1_1)-th wavelength shifter 341c that is dispersed in the (2_1)-th base resin 341a. Each of the (2_2)-th light-transmitting members 342 may include a (2_2)-th base resin 342a, a (2_2)-th light scatterer 342b that is dispersed in the (2_2)-th base resin 342a, and a (1_2)-th wavelength shifter 342c that is dispersed in the (2_2)-th base resin 342a. Each of the (2_3)-th light-transmitting members 343 may include a (2_3)-th base resin 343a, a (2_3)-th light scatterer 343b that is dispersed in the (2_3)-th base resin 343a, and a (1_3)-th wavelength shifter 343c that is dispersed in the (2_3)-th base resin 343a. The (2-1)-th, (2_2)-th, and (2_3)-th base resins 341a, 342a, and 343a may be substantially the same as, or similar to, the first base resin 330a of the first light-transmitting member 330 of FIG. 6, and thus, detailed descriptions thereof will be omitted. The (1_1)-th, (1_2)-th, and (1_3)-th wavelength shifters 341c, 342c, and 343c may be substantially the same as, or similar to, the first wavelength shifter 340c of the second light-transmitting member 340 of FIG. 6, and thus, detailed descriptions thereof will be omitted.

The (2_1)-th light-transmitting members 341 may be surrounded by first bank members BK1, the (2_2)-th light-transmitting members 342 may be surrounded by second bank members BK2, and the (2_3)-th light-transmitting members 343 may be surrounded by third bank members BK3.

In the first area DA_1, (3_1)-th, (3_2)-th, and (3_3)-th light-transmitting members 351, 352, and 353 may be sequentially arranged in each row along the second coordinate direction DR2 to be spaced apart from one another. (3_1)-th light-transmitting members 351, (3_2)-th light-transmitting members 352, and (3_3)-th light-transmitting members 353, which are disposed in the first area DA_1, may be formed of the same material as third light-transmitting members 350, which are disposed in the second area DA_2, but may have their widths or heights varied.

Each of the (3_1)-th light-transmitting members 351 may include a (3_1)-th base resin 351a, a (3_1)-th light scatterer 351b that is dispersed in the (3_1)-th base resin 351a, and a (2_1)-th wavelength shifter 351c that is dispersed in the (3_1)-th base resin 351a. Each of the (3_2)-th light-transmitting members 352 may include a (3_2)-th base resin 352a, a (3_2)-th light scatterer 352b that is dispersed in the (3_2)-th base resin 352a, and a (2_2)-th wavelength shifter 352c that is dispersed in the (3_2)-th base resin 352a. Each of the (3_3)-th light-transmitting members 353 may include a (3_3)-th base resin 353a, a (3_3)-th light scatterer 353b that is dispersed in the (3_3)-th base resin 353a, and a (2_3)-th wavelength shifter 353c that is dispersed in the (3_3)-th base resin 353a. The (3-1)-th, (3_2)-th, and (3_3)-th base resins 351a, 352a, and 353a may be substantially the same as, or similar to, the first base resin 330a of the first light-transmitting member 330 of FIG. 6, and thus, detailed descriptions thereof will be omitted. The (2_1)-th, (2_2)-th, and (2_3)-th wavelength shifters 351c, 352c, and 353c may be substantially the same as, or similar to, the second wavelength shifter 350c of the third light-transmitting member 350 of FIG. 6, and thus, detailed descriptions thereof will be omitted.

The (3_1)-th light-transmitting members 351 may be surrounded by first bank members BK1, the (3_2)-th light-transmitting members 352 may be surrounded by second bank members BK2, and the (3_3)-th light-transmitting members 353 may be surrounded by third bank members BK3.

The width and the height of the (2_1)-th light-transmitting members 341 and the (3_1)-th light-transmitting members 351 may be substantially the same as the width and the height of the (1_1)-th light-transmitting members 331, and thus, detailed descriptions thereof will be omitted. The width and the height of the (2_2)-th light-transmitting members 342 and the (3_2)-th light-transmitting members 352 may be substantially the same as the width and the height of the (1-2)-th light transmitting members 332 and thus, detailed descriptions thereof will be omitted. The width and the height of the (2_3)-th light-transmitting members 343 and the (3_3)-th light-transmitting members 353 may be substantially the same as the width and the height of the (1_3)-th light-transmitting members 333, and thus, detailed descriptions thereof will be omitted.

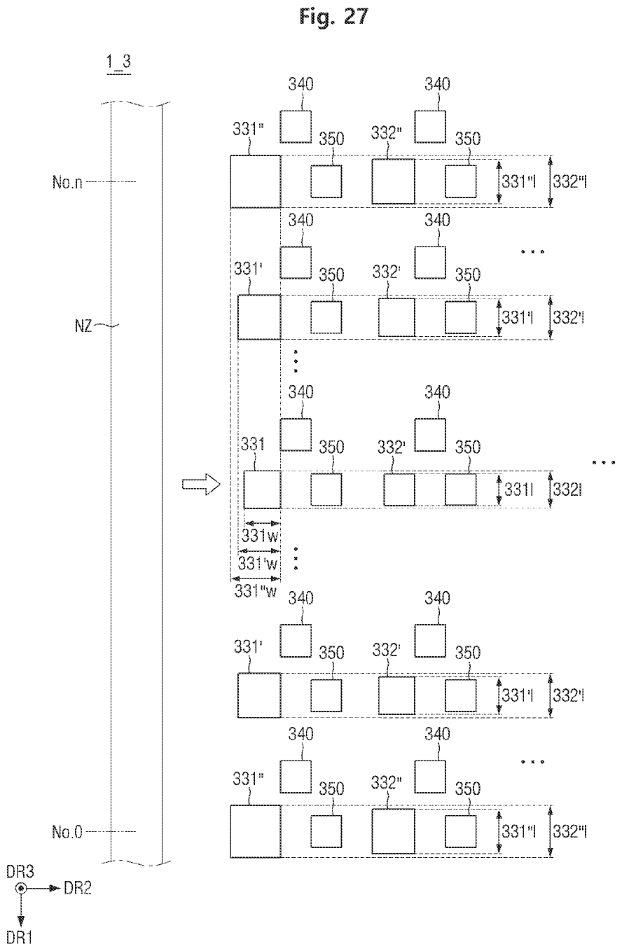

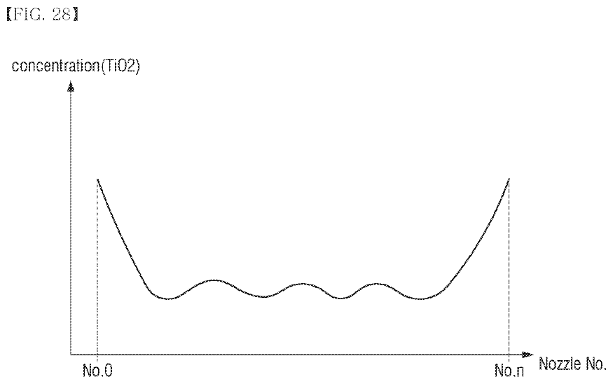

FIG. 27 is a plan view illustrating light-transmitting members in a first area of a light-transmitting part of a display device according to another embodiment of the disclosure and nozzles for applying a base resin and a light scatterer onto the light-transmitting member. FIG. 28 is a graph showing the concentration of light scatterers applied versus the locations of the nozzles of FIG. 27.

In the embodiments of FIGS. 27 and 28, the width and the height of light-transmitting members in a first area DA_1 of a display area DA of a display device 1_3 may be varied not only along a second coordinate direction DR2, but also along a first coordinate direction DR1. In other words, the light-transmitting members in the first area DA_1 may have their width and height varied in both row and column directions. For simplicity of explanation, FIG. 27 depicts an embodiment where the width and the length of the light-transmitting members are the same (i.e., the light-transmitting members are square). However, it should be understood that cases where the light-transmitting members are non-square shaped are also contemplated.

In the first area DA_1 of the display device 1_3, light-transmitting members arranged in columns along the first coordinate direction DR1 may have a shortest length and height at both ends of the first area DA_1, the length of the light-transmitting members decreases closer to the center, of the first area DA_1, and the height of the light-transmitting members in the first area DA_1 may increase closer to the center, in the first coordinate direction DR1, of the first area DA_1. In the first area DA_1 of the display device 1_3, the width of light-transmitting members arranged in rows may decrease along the second coordinate direction DR2, and the height of the light-transmitting members in the first area DA_1 may increase along the second coordinate direction DR2. The light-transmitting members arranged in rows along the second direction DR2 are as already described above, and thus, redundant descriptions thereof will be omitted. The light-transmitting members arranged in columns along the first coordinate direction DR1 will hereinafter be described.

The length and height of a (1_1)-th light-transmitting member 331, which is a light-transmitting pattern capable of transmitting incident light therethrough, may vary along the first coordinate direction DR1. In some embodiments, the length and height of second light-transmitting members 340 and third light-transmitting members 350, which are wavelength-shifting patterns, may not vary, but the disclosure is not limited thereto. Alternatively, not only the length and height of the (1_1)-th light-transmitting member 331, but also the length and height of the second light-transmitting members 340 and the third light-transmitting members 350 may vary along the first coordinate direction DR1.

The (1_1″)-th light transmitting members 331″ and (1_1′)-th light-transmitting members 331′ may be obtained by changing the length and height of the (1_1)-th light-transmitting member 331 along the first coordinate direction DR1. Specifically, referring to FIG. 27, the (1_1″)-th light transmitting members 331″ may be disposed at both ends of the first area DA_1, in the first coordinate direction DR1, (see FIG. 11), the (1_1)-th light-transmitting member 331 may be disposed in the middle of the column, and the (1_1′)-th light-transmitting members 331′ may be disposed between the (1_1)-th light-transmitting member 331 and the (1_1″)-th light transmitting members 331″. The width of light-transmitting members (331, 331′, and 331″) may decrease going from the (1_1″)-th light transmitting members 331″ to the (1_1′)-th light-transmitting members 331′ to the (1_1)-th light-transmitting member 331 along the first coordinate direction DR1.

The (1_2″)-th light transmitting members 332″ and (1_2′)-th light-transmitting members 332′ may be obtained by changing the length and height of the (1_2)-th light-transmitting members 332 along the first coordinate direction DR1. Specifically, referring to FIG. 27, the (1_2″)-th light transmitting members 332″ may be disposed at both ends, in the first coordinate direction DR1, of a column subsequent to the column including the (1_1)-th light-transmitting member 331, the (1_1′)-th light-transmitting members 331′, and the (1_1″)-th light transmitting members 331″, the (1_2)-th light-transmitting member 332 may be disposed in the middle of the column, and the (1_2′)-th light-transmitting members 332′ may be disposed between the (1_2)-th light-transmitting member 332 and the (1_2″)-th light transmitting members 332″. The width of light-transmitting members (332, 332′, and 332″) may decrease in the order of the (1_2″)-th light transmitting members 332″, the (1_2′)-th light-transmitting members 332′, and the (1_2)-th light-transmitting member 332 along the first coordinate direction DR1.

The concentration of light scatterers in an ink composition may vary depending on the locations of nozzles NZ passing over the first area DA_1. Specifically, referring to FIG. 28, the concentration of light scatterers ejected from nozzles NZ at the two ends of the first area DA_1 may be highest, and the concentration of the light scatterers may decrease closer to the middle of the first area DA_1. Thus, light-transmitting patterns at both ends, in the first coordinate direction DR1, of the first area DA_1 where the concentration of the light scatterers is highest, i.e., the (1_1″)-th light transmitting members 331″, may have a largest and light-transmitting patterns in the middle, in the first coordinate direction DR1, of the first area DA_1 where the concentration of the light scatterers is lowest, i.e., the (1_1)-th light-transmitting member 331, may have a smallest width in the second coordinate direction DR2. The horizontal axis of the plot in FIG. 28 correlates with nozzle numbers, which are indicated in FIG. 27 to correlate with the first coordinate direction DR1.

Those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a first substrate;
a second substrate facing the first substrate;
light-emitting elements disposed between the first and second substrates, the light-emitting elements forming first light-emitting areas;
first light-transmitting members disposed between the second substrate and the light-emitting elements; and
color filter members disposed between the second substrate and the first light-transmitting members,
wherein the color filter members form first filtering pattern areas that selectively transmit light and overlap with the first light-emitting areas,
wherein the first light-transmitting members overlap with the first light-emitting areas and the first filtering pattern areas and comprise light scatterers that scatter light, and
a width of the first light-transmitting members is greater than a width of the first light-emitting areas and a width of the first filtering pattern areas.

2. The display device of claim 1, further comprising:
second light-transmitting members disposed between the second substrate and the light-emitting elements and spaced apart from the first light-transmitting members,
wherein the light-emitting elements form second light-emitting areas that are spaced apart from the first light-emitting areas,
wherein the color filter members further comprise second filtering pattern areas that are spaced apart from the first filtering pattern areas and overlap with the second light-emitting areas,
wherein the second light-transmitting members overlap with the second light-emitting areas and the second filtering pattern areas and comprise light scatterers,
wherein a width of the second light-transmitting members is greater than a width of the second light-emitting areas and a width of the second filtering pattern areas, and
the width of the first light-transmitting members is greater than the width of the second light-transmitting members.

3. The display device of claim 2,
the width of the first light-emitting areas is substantially the same as the width of the second light-emitting areas, and
the width of the first filtering pattern areas is substantially the same as the width of the second filtering pattern areas.

4. The display device of claim 2,
the color filter members further comprise light-blocking areas disposed between the first filtering pattern areas and the second filtering pattern areas and block light;
the first light-emitting areas and the second light-emitting areas do not overlap with the light-blocking areas; and
the first light-transmitting members and the second light-transmitting members overlap with the light-blocking areas.

5. The display device of claim 1, wherein a height of the first light-transmitting members is less than a height of the second light-transmitting members.

6. The display device of claim 5, wherein a concentration of the light scatterers in the first light-transmitting members is higher than a concentration of the light scatterers in the second light-transmitting members.

7. The display device of claim 6, wherein
the first light-emitting areas emit first light,
the first light sequentially passes through the first light-transmitting members and the first filtering pattern areas,
the second light-emitting areas emit second light,
the second light sequentially passes through the second light-transmitting members and the second filtering pattern areas, and
a luminance of the first light sequentially passing through the first light-transmitting members and the first filtering pattern areas is substantially the same as a luminance of the second light sequentially passing through the second light-transmitting members and the second filtering pattern areas.

8. The display device of claim 7, wherein each of the first light and the second light has a wavelength of 380 nm to 500 nm and a peak wavelength of 440 nm to 480 nm.

9. The display device of claim 1, wherein
the first light-transmitting members comprise the light scatterers embedded in base resin,
the light scatterers comprise a metal oxide, and
the base resin comprise one of an epoxy resin, an acrylic resin, and an imide resin.

10. The display device of claim 9, wherein
the first light-transmitting members further comprise wave shifters embedded in the base resins, and
the wavelength shifters comprise a semiconductor nanocrystal material for shifting the wavelength of light emitted from the first light-emitting areas.

11. A display device comprising:
a light-emitting part emitting light; and
a light-transmitting part disposed on the light-emitting part, the light-transmitting part having a first area and a second area that is adjacent to a first side of the first area,
wherein the light-transmitting part comprises color filter members that selectively transmit light and a plurality of light-transmitting members disposed between the light-emitting part and the color filter members,
wherein the light-transmitting members comprise light scatterers, and
a width of the light-transmitting members increases along a first direction, in the first area of the light-transmitting part.

12. The display device of claim 11, wherein a height of the light-transmitting members increases along the first direction, in the first area of the light-transmitting part.

13. The display device of claim 12, wherein a concentration of the light scatterers in the light-transmitting members decreases along the first direction.

14. The display device of claim 13, wherein the width of the light-transmitting members is substantially uniform in the second area of the light-transmitting part.

15. The display device of claim 14, wherein the height of the light-transmitting members and the concentration of the light scatterers in the light-transmitting members are substantially constant in the second area of the light-transmitting part.

16. The display device of claim 15, wherein
the light-emitting part emits first light having a wavelength of 80 nm to 500 nm and a peak wavelength of 440 nm to 480 nm,
the first light passes through the light-transmitting part, and
a luminance of the first light passing through the first area of the light-transmitting part is substantially the same as a luminance of the second light passing through the second area of the light-transmitting part.

17. The display device of claim 11, wherein
the light-emitting part comprises a pixel-defining film that defines light-emitting areas emitting light,
the light-transmitting part further comprises a plurality of bank members that surround the light-transmitting members,
the color filter members of the light-transmitting part comprises light-blocking areas that define filtering pattern areas selectively transmitting light,
the bank members do not overlap with the light-emitting areas and the filtering pattern areas, and
the pixel-defining film does not overlap with the light-blocking areas.

18. The display device of claim 17, wherein in the first area of the light-transmitting part, a width of the bank members increases with reduced distance to the second area.

19. The display device of claim 18, wherein in the second area of the light-transmitting part, the width of the bank members is substantially uniform.

20. The display device of claim 11, the width of the light-transmitting members varies along a second direction that intersects the first direction, in the first area of the light-transmitting part.
